(19) United States
(12) Patent Application Publication
(10) Pub. No.: US 2026/0311958 A1
(43) Pub. Date: Oct. 8, 2026

(54) METHOD FOR OPERATING A PARTICLE BEAM APPARATUS, COMPUTER PROGRAM PRODUCT AND PARTICLE BEAM APPARATUS FOR CARRYING OUT THE METHOD

(71) Applicant: Carl Zeiss Microscopy GmbH, Jena (DE)

(72) Inventor: Bernd Hafner, Abtsgmuend (DE)

(73) Assignee: Carl Zeiss Microscopy GmbH, Jena (DE)

(21) Appl. No.: 19/574,361

(22) Filed: Mar. 22, 2026

(30) Foreign Application Priority Data
Mar. 24, 2025 (DE) 10 2025 111 168.5

(51) Int. Cl. H01J 37/21; H01J 37/244; H01J 37/28

(52) U.S. Cl. CPC H01J 37/21; H01J 37/244; H01J 37/28; H01J 2237/2448

(57) ABSTRACT

The invention relates to a method for operating a particle beam apparatus. The invention also relates to a computer program product and a particle beam apparatus for carrying out the method. The method comprises setting a control parameter for controlling an objective lens in such a way that a particle beam from the particle beam apparatus is focused onto a first region of a first unit using the objective lens; determining a first value of the control parameter, for which the particle beam is focused onto the first region; determining a first distance between an outer boundary of the objective lens and the first region; second setting of the control parameter for controlling the objective lens in such a way that the particle beam is focused onto a second region of a second unit using the objective lens; determining a second value of the control parameter, for which the particle beam is focused onto the second region; determining a second distance between the outer boundary of the objective lens and the second region; determining a difference between the first distance and the second distance; and outputting the difference and/or an absolute value of the difference using an output unit belonging to the particle beam apparatus.

### CROSS-REFERENCE TO RELATED APPLICATION

This application claims the priority of German patent application no. 10 2025 111 168.5, filed on Mar. 24, 2025 and incorporated herein by reference.

The invention relates to a method for operating a particle beam apparatus. The invention furthermore relates to a computer program product and a particle beam apparatus for carrying out the method according to the invention. For example, the particle beam apparatus is embodied as an electron beam apparatus and/or as an ion beam apparatus.

Electron beam apparatuses, in particular a scanning electron microscope (also referred to as SEM below) and/or a transmission electron microscope (also referred to as TEM below), are used to examine objects (samples) in order to gain knowledge about the properties and the behaviour under certain conditions.

In an SEM, an electron beam (also referred to as primary electron beam below) is generated by way of a beam generator and focused onto an object to be examined by way of a beam guiding system. The primary electron beam is guided in a raster-scanning manner over a surface of the object to be examined by means of a deflection device. In the process, the electrons of the primary electron beam interact with the object to be examined. As a consequence of the interaction, in particular electrons are emitted by the object (so-called secondary electrons) and electrons of the primary electron beam are backscattered (so-called backscattered electrons). The secondary electrons and backscattered electrons are detected and used for image generation. An image representation of the object to be examined is thus obtained. Furthermore, interaction radiation, for example x-ray radiation and/or cathodoluminescence, is generated as a consequence of the interaction. In particular, the interaction radiation is used to analyse the object.

In the case of a TEM, a primary electron beam is likewise generated by means of a beam generator and focused on an object to be examined by means of a beam guiding system.

The primary electron beam radiates through the object to be examined. When the primary electron beam passes through the object to be examined, the electrons of the primary electron beam interact with the material of the object to be examined. The electrons passing through the object to be examined are imaged on a luminescent screen or on a detector (for example a camera) by a system consisting of an objective and a projection unit. Here, imaging may also take place in the scanning mode of a TEM. Usually, such a TEM is referred to as STEM. Additionally, the use of a further detector to detect electrons backscattered at the object to be examined and/or secondary electrons emitted by the object to be examined can be provided, in order to image an object to be examined.

Furthermore, the prior art discloses the use of combination apparatuses for examining objects, in which both electrons and ions are able to be guided onto an object to be examined. For example, additionally equipping an SEM with an ion beam column is known. An ion beam generator arranged in the ion beam column is used to generate ions that are used for the preparation of an object (for example ablating material from the object or applying material to the object) or else for imaging. The SEM serves here in particular to observe the preparation, but also for further examination of the prepared or unprepared object.

Material is applied to the object in a particle beam apparatus using a gas feed. The known particle beam apparatus is a combination apparatus that provides both an electron beam and an ion beam. The particle beam apparatus comprises an electron beam column and an ion beam column. The electron beam column provides an electron beam that is focused onto an object. The object is arranged in a sample chamber kept under vacuum. The ion beam column provides an ion beam that is likewise focused onto the object. For example, a layer of the surface of the object is removed by means of the ion beam. A further surface of the object is exposed once said layer has been removed. By means of a gas feed device, a gaseous precursor substance—a so-called precursor—may be admitted into the sample chamber. It is known to embody the gas feed device with an acicular device, which may be arranged quite close to a position of the object at a distance of a few μm, such that the gaseous precursor substance may be guided to this position as accurately as possible and with a high concentration. A layer of a substance is deposited on the surface of the object as a result of the interaction of the ion beam with the gaseous precursor substance. For example, it is known for gaseous phenanthrene to be admitted as gaseous precursor substance into the sample chamber by means of the gas feed device. Essentially a layer of carbon or a carbon-containing layer then deposits on the surface of the object. It is also known to use a gaseous precursor substance comprising metal in order to deposit a metal or a metal-containing layer on the surface of the object. However, the depositions are not limited to carbon and/or metals. Rather, any desired substances may be deposited on the surface of the object, for example semiconductors, non-conductors or other compounds. Furthermore, it is known for the gaseous precursor substance to be used for ablating material from the object upon interaction with a particle beam.

It is known to arrange the object on a movable object stage for the purpose of orientation and/or positioning of the object in the sample chamber of the particle beam apparatus. The known object stage is embodied so as to be movable in three directions arranged perpendicular to one another, specifically in an x-direction of the object stage (first stage axis), in a y-direction of the object stage (second stage axis) and in a z-direction of the object stage (third stage axis). Moreover, the known object stage can be rotated about two axes of rotation of the object stage (axes of rotation of the stage) which are arranged perpendicular to one another. Furthermore, it is known to move the object stage about or along further axes. Moreover, multiple provision of axes along a predefinable direction is known, about or along which the object stage is movable.

Above and also below, the positioning of the object (or another unit) is understood to mean an arrangement of the object (or the unit) at a specific position in space relative to an initial position in the form of a zero point. By way of example, the specific position is given by three coordinates, in particular by three coordinates of a Cartesian coordinate system. The origin of the coordinate system is then the initial position.

Above and also below, the orientation of the object (or another unit) is understood to mean an orientation of a surface of the object (or the other unit) with respect to at least one predefinable axis or with respect to a plurality of predefinable axes. By way of example, the surface of the object is (i) arranged in a manner tilted or rotated at a specific angle with respect to the predefinable axis, or (ii) arranged at specific angles with respect to a plurality of predefinable axes.

In order to determine the orientation and/or the positioning of the object arranged on the movable object stage, methods are already known from the prior art, and will be explained below.

By way of example, it is known to generate an electron-optical image of the object arranged on the movable object stage by means of the particle beam apparatus and to determine the orientation and/or the positioning of the object on the basis of the recorded electron-optical image of the object. The electron-optical image is generated for example by detecting secondary electrons and backscattered electrons resulting from an interaction of a primary electron beam with the object.

Furthermore, it is known to generate a light-optical image of the object arranged on the movable object stage by means of a camera and to determine the orientation and/or the positioning of the object on the basis of the light-optical image of the object.

Moreover, it is known from the prior art to use stepper motors of a movement device for moving the object stage to determine and control the orientation and/or the positioning of the object arranged on the movable object stage. The known stepper motors comprise step counters for determining and controlling the aforementioned orientation and/or the positioning. By means of the number of steps carried out by one stepper motor or a plurality of stepper motors of the movement device, the aforementioned orientation and/or positioning of the object arranged on the movable object stage relative to a predefinable initial position can be determined and/or controlled.

Use of a gas feed device with an acicular device to feed at least one gas has already been explained further above. It is known that the acicular device is embodied so as to be movable in three directions arranged perpendicular to one another, specifically in an x-direction of the acicular device (first device axis), in a y-direction of the acicular device (second device axis) and in a z-direction of the acicular device (third device axis). Moreover, the known acicular device can be rotated for example about two axes of rotation of the acicular device (axes of rotation of the device) which are arranged perpendicular to one another. Furthermore, it is known to move the acicular device about or along further axes. Moreover, multiple provision of axes along a predefinable direction is known, about or along which the acicular device is movable. The acicular device is oriented and/or positioned, for example, in a similar manner to the methods explained further above with regard to the object arranged on the movable object stage. Reference is made to these explanations, which also apply here.

In order to determine electrical parameters of an object (for example a component of the semiconductor industry), a method is known in which measuring devices with a tapering formation are guided to contact points arranged on the object. If the measuring devices with a tapering formation are arranged at the contact points, the electrical parameters can be determined. The abovementioned method is known as “nanoprobing”. With the abovementioned method, it is possible to identify and locate electrical faults in the form of short circuits, interruptions, resistance contacts and creepage distances. It is known to arrange such measuring devices with a tapering formation, for example, in a scanning electron microscope (SEM) and/or in an atomic force microscope (AFM). It is also known to move the measuring devices with a tapering formation using piezoelectric drives, such that the measuring devices with a tapering formation can be arranged at the contact points of the object. The measuring devices with a tapering formation are oriented and/or positioned, for example, in a similar manner to the methods explained further above with regard to the object arranged on the movable object stage. Reference is made to the explanations given above, which also apply here.

For example, in order to guide the acicular device of the gas feed device described above to the object, it is desirable to know as precisely as possible the distance between the object and the acicular device. The same applies to the abovementioned measuring devices with a tapering formation. Here, too, it is desirable to know as precisely as possible the distance between the object and the measuring devices with a tapering formation.

As regards the prior art, reference is made to U.S. Pat. No. 10,872,744 B2 and DE 10 2014 220 122 A1.

The invention is based on the object of specifying a further method for operating a particle beam apparatus, with which the distance between a first unit and a second unit, which are arranged in a sample chamber of the particle beam apparatus, is determined. For example, the first unit is an acicular device of a gas feed unit and/or a unit comprising measuring devices with a tapering formation. For example, the second unit is embodied as an object.

According to the invention, this object is achieved by a method having the features of claim 1. A computer program product according to the invention comprising program code which controls a particle beam apparatus for carrying out a method according to the invention is given by the features of claim 12. Furthermore, a particle beam apparatus according to the invention for imaging, analysing and/or processing an object having the features of claim 13 is given. Further features of the invention emerge from the following description, the appended claims and/or the appended drawings.

The method according to the invention is used to operate a particle beam apparatus. The particle beam apparatus has for example at least one beam generator for generating a particle beam comprising charged particles. In particular, the charged particles are electrons or ions. Furthermore, the particle beam apparatus has, for example, at least one objective lens for focusing the particle beam onto an object or another unit, wherein the object and/or the unit are/is arranged in a sample chamber of the particle beam apparatus.

The method according to the invention comprises first setting of a control parameter for controlling the objective lens of the particle beam apparatus using a control unit belonging to the particle beam apparatus in such a way that the particle beam from the particle beam apparatus is focused onto a first region of at least one first unit, which is arranged in a sample chamber of the particle beam apparatus, using the objective lens. The aforementioned control parameter is, for example, a control current or a control voltage. A control unit of the particle beam apparatus and/or a control unit assigned to the particle beam apparatus is/are used as the aforementioned control unit, for example. For example, provision is made for the control unit and the particle beam apparatus to be arranged in a locally separate manner. In particular, provision is made for the control unit to be connected to the particle beam apparatus using signal technology by means of at least one cable line and/or by means of at least one wireless connection.

The first setting of the control parameter comprises, for example, setting the control parameter in such a way that the first region of the at least one first unit is arranged in a first focal plane of the objective lens. Additionally or alternatively, provision is made for the first setting of the control parameter to comprise setting the control parameter to an arbitrary value. Furthermore, the first region of the at least one first unit is arranged by moving the at least one first unit in a focal plane of the objective lens determined by the arbitrary value of the control parameter.

Any unit arranged in the sample chamber of the particle beam apparatus can be used as at least one first unit. Embodiments of the at least one first unit are explained further below.

In addition, the method according to the invention comprises determining, using a processor unit belonging to the particle beam apparatus, a first value of the control parameter, for which the particle beam is focused onto the first region of the at least one first unit. A processor unit of the particle beam apparatus and/or a processor unit assigned to the particle beam apparatus is/are used as the aforementioned processor unit, for example. For example, provision is made for the processor unit and the particle beam apparatus to be arranged in a locally separate manner. In particular, provision is made for the processor unit to be connected to the particle beam apparatus using signal technology by means of at least one cable line and/or by means of at least one wireless connection.

Furthermore, the method according to the invention comprises determining a first distance between an outer boundary of the objective lens and the first region of the at least one first unit using the first value of the control parameter and the processor unit. Basically, the first distance is a focal plane distance which is also referred to as the working distance. For example, the first distance is a shortest connection of all possible connections between any point on the outer boundary of the objective lens and the first region of the at least one first unit.

The method according to the invention also comprises second setting of the control parameter for controlling the objective lens using the control unit in such a way that the particle beam from the particle beam apparatus is focused onto a second region of at least one second unit, which is arranged in the sample chamber of the particle beam apparatus, using the objective lens. The second setting of the control parameter comprises, for example, setting the control parameter in such a way that the second region of the at least one second unit is arranged in a second focal plane of the objective lens. Additionally or alternatively, provision is made for the second setting of the control parameter to comprise setting the control parameter to a further arbitrary value. Furthermore, the second region of the at least one second unit is arranged by moving the at least one second unit in a focal plane of the objective lens determined by the further arbitrary value.

Any unit arranged in the sample chamber of the particle beam apparatus can be used as at least one second unit. Embodiments of the at least one second unit are explained further below.

Furthermore, the method according to the invention comprises determining, using the processor unit, a second value of the control parameter, for which the particle beam is focused onto the second region of the at least one second unit.

In addition, the method according to the invention comprises determining a second distance between the outer boundary of the objective lens and the second region of the at least one second unit using the second value of the control parameter and the processor unit of the particle beam apparatus. Basically, the second distance is also a focal plane distance which is also referred to as the working distance. For example, the second distance is a shortest connection of all possible connections between any point on the outer boundary of the objective lens and the second region of the at least one second unit.

The method according to the invention also comprises determining a difference between the first distance and the second distance using the processor unit. Provision is also made for the difference and/or an absolute value of the difference to be output on an output unit belonging to the particle beam apparatus. A display unit of the particle beam apparatus and/or a display unit assigned to the particle beam apparatus is/are used as the aforementioned output unit, for example. For example, provision is made for the output unit and the particle beam apparatus to be arranged in a locally separate manner. In particular, provision is made for the output unit to be connected to the particle beam apparatus using signal technology by means of at least one cable line and/or by means of at least one wireless connection. In particular, provision is made for at least one monitor and/or at least one loudspeaker and/or at least one light signal system to be used as the output unit. The output is effected using the at least one monitor and/or using the at least one light signal system, for example by displaying a numerical value and/or by displaying a colour code and/or by displaying a 3D representation representing the difference and/or by displaying the difference and/or the absolute value of the difference with a pointer and/or by displaying a flashing frequency and/or by displaying a brightness. Additionally or alternatively, the difference and/or the absolute value of the difference is/are acoustically output, for example, by a sound frequency and/or a pitch and/or a pulse frequency and/or a sequence of sounds using a loudspeaker.

It is explicitly pointed out that the at least one first unit may include numerous further units. For example, the at least one first unit includes a predefinable number of first subunits. In particular, a measuring device with a tapering formation is used as a first subunit of the at least one first unit. For example, the at least one first unit has numerous measuring devices with a tapering formation. It is also explicitly pointed out that the at least one second unit may include numerous further units. For example, the at least one second unit includes a predefinable number of second subunits. In particular, a section of the object is used as a second subunit of the at least one second unit. Further embodiments of the at least one first unit and/or the at least one second unit are explained further below.

The method according to the invention is a further method for operating the particle beam apparatus, with which the distance between at least one first unit and at least one second unit, which are arranged in a sample chamber of the particle beam apparatus, is determined.

In one embodiment of the method according to the invention, the following method steps are additionally or alternatively provided: When the particle beam is focused onto the first region of the at least one first unit, (i) detecting interaction particles and/or interaction radiation using at least one detector of the particle beam apparatus, wherein the interaction particles and/or the interaction radiation result(s) from an interaction of the particle beam with the first region of the at least one first unit, (ii) generating a first image of the first region of the at least one first unit using the processor unit based on the detected interaction particles and/or the detected interaction radiation, and (iii) displaying the generated first image of the first region of the at least one first unit using the output unit. Additionally or alternatively, the following method steps are provided: When the particle beam is focused onto the second region of the at least one second unit, (iv) detecting interaction particles and/or interaction radiation using the at least one detector of the particle beam apparatus, wherein the interaction particles and/or the interaction radiation result(s) from an interaction of the particle beam with the second region of the at least one second unit, (v) generating a second image of the second region of the at least one second unit using the processor unit based on the detected interaction particles and/or the detected interaction radiation, and (vi) displaying the generated second image of the second region of the at least one second unit using the output unit. The above embodiments ensure that, in addition to the difference or the absolute value of the difference (i.e., in addition to the distance between the first region of the at least one first unit and the second region of the at least one second unit), particle-optical images of the first region of the at least one first unit and/or of the second region of the at least one second unit are also presented using the output unit.

In a further embodiment of the method according to the invention, provision is additionally or alternatively made for the generated first image of the first region of the at least one first unit to also be displayed on the output unit when the particle beam is focused onto the second region of the at least one second unit and/or when the generated second image of the second region of the at least one second unit is displayed on the output unit. This embodiment of the method according to the invention ensures that both the generated first image and the generated second image are presented using the output unit even if the particle beam is focused only onto one of the regions, that is to say onto the first region of the at least one first unit or onto the second region of the at least one second unit.

In yet another embodiment of the method according to the invention, provision is additionally or alternatively made for the first distance and/or the second distance to be output using the output unit. In other words, the first working distance and/or the second working distance are/is output using the output unit.

In yet another embodiment of the method according to the invention, provision is additionally or alternatively made for a region which extends both along a first direction with a first length and along a second direction with a second length to be used as the first region. Furthermore, a region which extends both along the first direction with the first length and along the second direction with the second length is used as the second region. Basically, the first region of the at least one first unit and the second region of the at least one second unit have an identical design in a first dimension (first direction) and in a second dimension (second direction). Basically, in this embodiment of the method according to the invention, the first region of the at least one first unit and the second region of the at least one second unit differ only by their distance from each other, wherein the distance extends along a third dimension (third direction). For example, the first direction, the second direction and the third direction are each arranged perpendicular to each other.

In a further embodiment of the method according to the invention, provision is additionally or alternatively made for the at least one first unit to be moved in the sample chamber using a first movement device. Additionally or alternatively, provision is made for the at least one second unit to be moved in the sample chamber using a second movement device.

For example, a movement device having a first movement unit, a second movement unit and/or a third movement unit is used as the first movement device. For example, the first movement unit provides a movement of the at least one first unit along a first axis of the at least one first unit. Furthermore, for example, the second movement unit provides a movement of the at least one first unit along a second axis of the at least one first unit. In addition, for example, the third movement unit provides a movement of the at least one first unit along a third axis of the at least one first unit. Furthermore, the first movement device may comprise a fourth movement unit for providing a rotation of the at least one first unit about a first axis of rotation of the at least one first unit and/or a fifth movement unit for providing a rotation of the at least one first unit about a second axis of rotation of the at least one first unit. It is explicitly pointed out that the first movement device is not restricted to the aforementioned first movement device. On the contrary, any movement device that is suitable for the invention may be used as the first movement device.

For example, a movement device having a further first movement unit, a further second movement unit and/or a further third movement unit is used as the second movement device. For example, the further first movement unit provides a movement of the at least one second unit along a further first axis of the at least one second unit. Furthermore, for example, the further second movement unit provides a movement of the at least one second unit along a further second axis of the at least one second unit. In addition, for example, the further third movement unit provides a movement of the at least one second unit along a further third axis of the at least one second unit. Furthermore, the second movement device may comprise a further fourth movement unit for providing a rotation of the at least one second unit about a further first axis of rotation of the at least one second unit and/or a further fifth movement unit for providing a rotation of the at least one second unit about a further second axis of rotation of the at least one second unit. It is explicitly pointed out that the second movement device is not restricted to the aforementioned second movement device. On the contrary, any movement device that is suitable for the invention may be used as the second movement device.

In yet another embodiment of the method according to the invention, provision is additionally or alternatively made for the distance between the at least one first unit and the at least one second unit to be determined again. This is advantageous, for example, after a movement of the at least one first unit and/or the at least one second unit. This embodiment of the method according to the invention comprises third setting of the control parameter for controlling the objective lens of the particle beam apparatus using the control unit in such a way that the particle beam from the particle beam apparatus is focused onto a further first region of the at least one first unit using the objective lens. The further first region of the at least one first unit is, for example, identical to the already abovementioned first region of the at least one first unit. The third setting of the control parameter comprises, for example, setting the control parameter in such a way that the further first region of the at least one first unit is arranged in the focal plane of the objective lens. Additionally or alternatively, provision is made for the third setting of the control parameter to comprise setting the control parameter to yet a further arbitrary value. Furthermore, the further first region of the at least one first unit is arranged by moving the at least one first unit in a focal plane of the objective lens determined by the yet further arbitrary value. In addition, this embodiment of the method according to the invention comprises determining, using the processor unit, a further first value of the control parameter, for which the particle beam is focused onto the further first region of the at least one first unit. Furthermore, this embodiment of the method according to the invention comprises determining a further first distance between the outer boundary of the objective lens and the further first region of the at least one first unit using the further first value of the control parameter and the processor unit. Basically, the further first distance is a focal plane distance which is also referred to as the working distance. For example, the further first distance is a shortest connection of all possible connections between any point on the outer boundary of the objective lens and the further first region of the at least one first unit. In addition, this embodiment of the method according to the invention also comprises fourth setting of the control parameter for controlling the objective lens using the control unit in such a way that the particle beam from the particle beam apparatus is focused onto a further second region of the at least one second unit, which is arranged in the sample chamber of the particle beam apparatus, using the objective lens. The further second region of the at least one second unit is, for example, identical to the already abovementioned second region of the at least one second unit. The fourth setting of the control parameter comprises, for example, setting the control parameter in such a way that the further second region of the at least one second unit is arranged in a focal plane of the objective lens. Additionally or alternatively, provision is made for the fourth setting of the control parameter to comprise setting the control parameter to yet a further arbitrary value. Furthermore, the further second region of the at least one second unit is arranged by moving the at least one second unit in a focal plane of the objective lens determined by the yet further arbitrary value. In addition, this embodiment of the method according to the invention also comprises determining, using the processor unit, a further second value of the control parameter, for which the particle beam is focused onto the further second region of the at least one second unit. Furthermore, this embodiment of the method according to the invention comprises determining a further second distance between the outer boundary of the objective lens and the further second region of the at least one second unit using the further second value of the control parameter and the processor unit of the particle beam apparatus. Basically, the further second distance is also a focal plane distance which is also referred to as the working distance. For example, the further second distance is a shortest connection of all possible connections between any point on the outer boundary of the objective lens and the further second region of the at least one second unit. This embodiment of the method according to the invention also comprises determining a further difference between the further first distance and the further second distance using the processor unit. Provision is also made for the further difference and/or an absolute value of the further difference to be output using the output unit belonging to the particle beam apparatus. In particular, provision is made for at least one monitor and/or at least one loudspeaker and/or at least one light signal unit to be used as the output unit. The output is effected using the at least one monitor and/or using the at least one light signal system, for example by displaying a numerical value and/or by displaying a colour code and/or by displaying a 3D representation representing the further difference and/or by displaying the further difference and/or the absolute value of the further difference with a pointer and/or by displaying a flashing frequency and/or by displaying a brightness. Additionally or alternatively, the further difference and/or the absolute value of the further difference is/are acoustically output, for example, by a sound frequency and/or a pitch and/or a pulse frequency and/or a sequence of sounds using a loudspeaker.

In yet another embodiment of the method according to the invention, the following method steps are additionally or alternatively provided: When the particle beam is focused onto the further first region of the at least one first unit, (i) detecting interaction particles and/or interaction radiation using at least one detector unit of the particle beam apparatus, wherein the interaction particles and/or the interaction radiation result(s) from an interaction of the particle beam with the further first region of the at least one first unit, (ii) generating a further first image of the further first region of the at least one first unit using the processor unit based on the detected interaction particles and/or the detected interaction radiation, and (iii) displaying the generated further first image of the further first region of the at least one first unit using the output unit. In one embodiment, a detector unit which is identical to the detector already mentioned above is used. Additionally or alternatively, the following method steps are provided: When the particle beam is focused onto the further second region of the at least one second unit, (iv) detecting interaction particles and/or interaction radiation using the at least one detector unit of the particle beam apparatus, wherein the interaction particles and/or the interaction radiation result(s) from an interaction of the particle beam with the further second region of the at least one second unit, (v) generating a further second image of the further second region of the at least one second unit using the processor unit based on the detected interaction particles and/or the detected interaction radiation, and (vi) displaying the generated further second image of the further second region of the at least one second unit using the output unit. The above embodiments ensure that, in addition to the further difference or the absolute value of the further difference (i.e., in addition to the distance between the further first region of the at least one first unit and the further second region of the at least one second unit), particle-optical images of the further first region of the at least one first unit and/or of the further second region of the at least one second unit are also presented using the output unit.

In one embodiment of the method according to the invention, provision is additionally or alternatively made for the generated further first image of the further first region of the at least one first unit to also be displayed using the output unit when the particle beam is focused onto the further second region of the at least one second unit and/or when the generated further second image of the further second region of the at least one second unit is displayed using the output unit. This embodiment of the method according to the invention ensures that the generated further first image and the generated further second image are presented using the output unit even if the particle beam is focused only onto one of the regions, that is to say onto the further first region of the at least one first unit or onto the further second region of the at least one second unit.

In a further embodiment of the method according to the invention, provision is additionally or alternatively made for an electron beam apparatus and/or an ion beam apparatus to be used as the particle beam apparatus.

In yet another embodiment of the method according to the invention, provision is additionally or alternatively made for at least one of the following units to be used as the at least one first unit and/or as the at least one second unit: (i) a manipulator for arranging the object or a portion of the object extracted from the object. For example, the manipulator has an acicular and/or tapering formation. Additionally or alternatively, provision is made for the manipulator to be formed with a gripping device; (ii) a measuring device having a tapering formation, for example. In particular, a measuring device for making electrical contact and/or for making mechanical contact and/or for dissipating electrical current and/or for supplying electrical current and/or for measuring an electrical potential and/or for supplying an electrical potential is used; (iii) a gas feed device; (iv) a detection unit; and (v) an object to be examined, analysed and/or processed with the particle beam apparatus. It is explicitly pointed out that the above list is not an exhaustive list. On the contrary, any unit suitable for the invention can be used as the at least one first unit and/or as the at least one second unit.

All embodiments of the method according to the invention above and below are not restricted to the explained order of the method steps. The invention also encompasses different orders of the method steps that are suitable for achieving the object within the meaning of the invention. Alternatively or additionally, in the method according to the invention, provision is also made to carry out at least two method steps in parallel. Furthermore, the embodiments of the method according to the invention above and below are not restricted to the complete scope of all the method steps mentioned above or further below. In particular, provision is made for individual or a plurality of the abovementioned or following method steps to be omitted in further embodiments.

The invention also relates to a computer program product comprising program code that is able to be loaded or is loaded into a processor unit belonging to a particle beam apparatus, wherein the program code, when executed in the processor unit, controls the particle beam apparatus such that a method according to the invention having at least one of the abovementioned or following features or having a combination of at least two of the abovementioned or following features is carried out. In other words, the invention also relates to a non-volatile and computer-readable medium comprising software that is able to be loaded or is loaded into a processor unit belonging to a particle beam apparatus, wherein the software, when executed in the processor unit, controls the particle beam apparatus such that a method according to the invention having at least one of the abovementioned or following features or having a combination of at least two of the abovementioned or following features is carried out. The software comprises executable code for carrying out at least one method step.

In this respect, the invention also relates to a processor unit which belongs to a particle beam apparatus and is configured to carry out a method according to the invention having at least one of the abovementioned or following features or having a combination of at least two of the abovementioned or following features.

With regard to the processor unit belonging to the particle beam apparatus, reference is made to the explanations further above, which also apply here.

The invention furthermore relates to a particle beam apparatus for imaging, analysing and/or processing an object, wherein the particle beam apparatus has already been explained further above and will be specified in detail further below. The particle beam apparatus according to the invention serves for carrying out the method according to the invention. The particle beam apparatus according to the invention comprises at least one beam generator for generating a particle beam comprising charged particles. The charged particles are electrons or ions, for example. Moreover, the particle beam apparatus according to the invention comprises a sample chamber. Furthermore, the particle beam apparatus according to the invention comprises at least one first unit and at least one second unit, wherein the at least one first unit and the at least one second unit are arranged in the sample chamber. In addition, the particle beam apparatus according to the invention has at least one objective lens for focusing the at least one particle beam onto the object, onto the at least one first unit and/or onto the at least one second unit. In addition, the particle beam apparatus according to the invention has a control unit for controlling the objective lens and an output unit. Furthermore, the particle beam apparatus according to the invention comprises at least one processor unit into which a computer program product having the features already mentioned further above for carrying out the method according to the invention is loaded.

In particular, provision is made for the particle beam apparatus according to the invention to have at least one detector for detecting interaction particles and/or interaction radiation, wherein the interaction particles and/or the interaction radiation result(s) from an interaction of the particle beam with the object.

In one embodiment of the particle beam apparatus according to the invention, provision is additionally or alternatively made for the particle beam apparatus according to the invention to have a first movement device for moving the at least one first unit and/or a second movement device for moving the at least one second unit.

For example, the first movement device has a first movement unit, a second movement unit and/or a third movement unit. For example, the first movement unit provides a movement of the at least one first unit along a first axis of the at least one first unit. Furthermore, for example, the second movement unit provides a movement of the at least one first unit along a second axis of the at least one first unit. In addition, for example, the third movement unit provides a movement of the at least one first unit along a third axis of the at least one first unit. Furthermore, the first movement device may comprise a fourth movement unit for providing a rotation of the at least one first unit about a first axis of rotation of the at least one first unit and/or a fifth movement unit for providing a rotation of the at least one first unit about a second axis of rotation of the at least one first unit. It is explicitly pointed out that the first movement device is not restricted to the aforementioned first movement device. On the contrary, any movement device that is suitable for the invention may be used as the first movement device.

For example, the second movement device has a further first movement unit, a further second movement unit and/or a further third movement unit. For example, the further first movement unit provides a movement of the at least one second unit along a further first axis of the at least one second unit. Furthermore, for example, the further second movement unit provides a movement of the at least one second unit along a further second axis of the at least one second unit. In addition, for example, the further third movement unit provides a movement of the at least one second unit along a further third axis of the at least one second unit. Furthermore, the second movement device may comprise a further fourth movement unit for providing a rotation of the at least one second unit about a further first axis of rotation of the at least one second unit and/or a further fifth movement unit for providing a rotation of the at least one second unit about a further second axis of rotation of the at least one second unit. It is explicitly pointed out that the second movement device is not restricted to the aforementioned second movement device. On the contrary, any movement device that is suitable for the invention may be used as the second movement device.

In a further embodiment of the particle beam apparatus according to the invention, provision is additionally or alternatively made for the at least one first unit and/or the at least one second unit to be embodied as at least one of the following units: (i) as a manipulator for arranging the object or a portion of the object extracted from the object. For example, the manipulator has an acicular and/or tapering formation. Additionally or alternatively, provision is made for the manipulator to be formed with a gripping device; (ii) as a measuring device having a tapering formation, for example. In particular, the measuring device is designed to make electrical contact and/or to make mechanical contact and/or to dissipate electrical current and/or to supply electrical current and/or to measure an electrical potential and/or to supply an electrical potential; (iii) as a gas feed device; (iv) as a detection unit; and (v) as an object to be examined, analysed and/or processed with the particle beam apparatus. It is explicitly pointed out that the above list is not an exhaustive list. On the contrary, the at least one first unit and/or the at least one second unit can be embodied as any unit suitable for the invention.

In yet another embodiment of the particle beam apparatus according to the invention, provision is additionally or alternatively made for the beam generator to be embodied as a first beam generator and for the particle beam to be embodied as a first particle beam comprising first charged particles. The objective lens is embodied as a first objective lens for focusing the first particle beam onto the object. Furthermore, the particle beam apparatus according to the invention comprises at least one second beam generator for generating a second particle beam comprising second charged particles. Moreover, the particle beam apparatus according to the invention comprises at least one second objective lens for focusing the second particle beam onto the object. The second charged particles are electrons or ions, for example.

In yet another embodiment of the particle beam apparatus according to the invention, provision is additionally or alternatively made for the particle beam apparatus to be embodied as an electron beam apparatus and/or as an ion beam apparatus.

Further practical embodiments and advantages of the invention are described below in association with the drawings, in which:

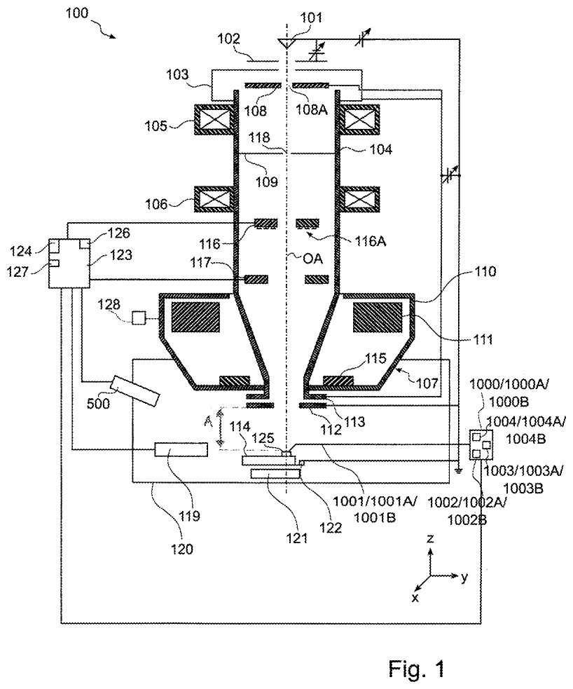

FIG. 1 shows a schematic illustration of a first embodiment of a particle beam apparatus;

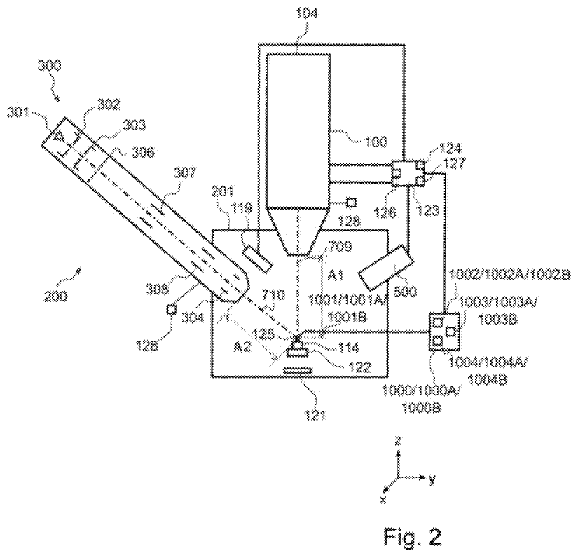

FIG. 2 shows a schematic illustration of a second embodiment of a particle beam apparatus;

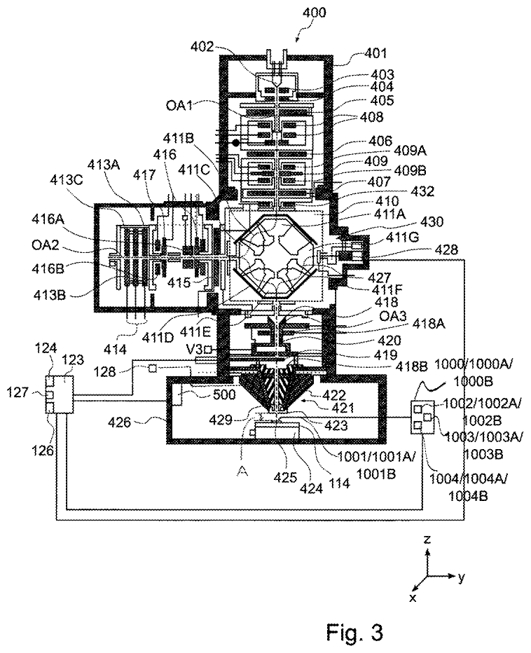

FIG. 3 shows a schematic illustration of a third embodiment of a particle beam apparatus;

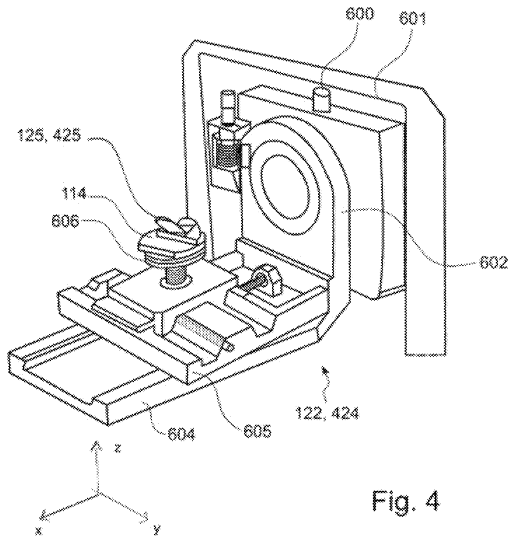

FIG. 4 shows a schematic illustration of one embodiment of an object stage of a particle beam apparatus;

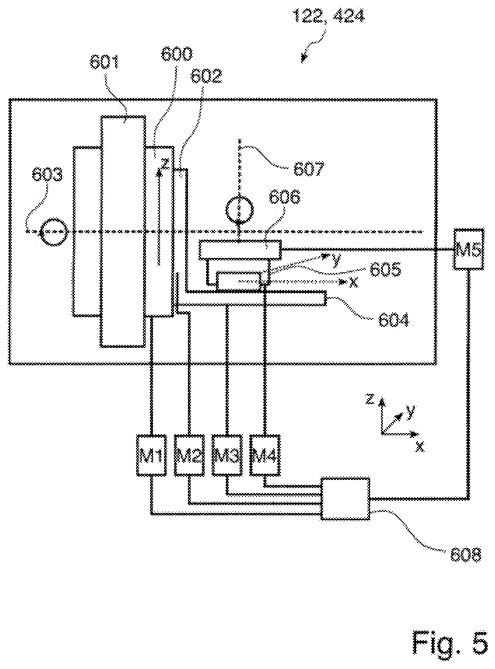

FIG. 5 shows a further illustration of the embodiment of the object stage according to FIG. 4;

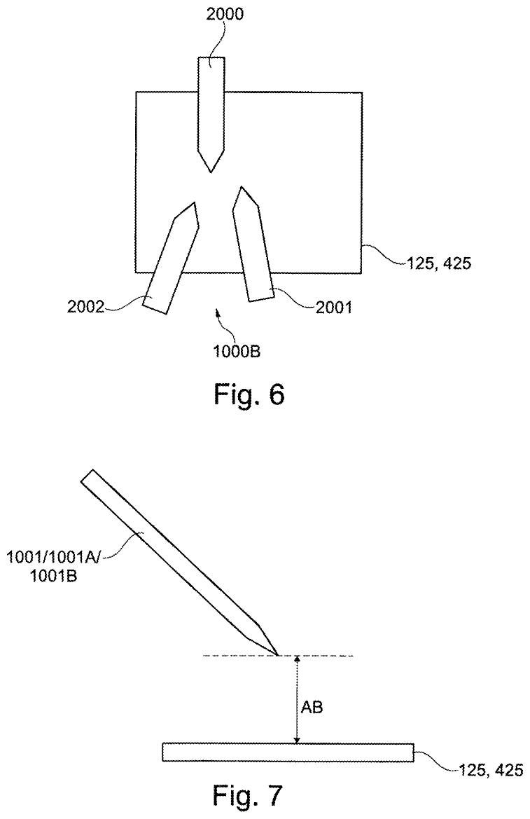

FIG. 6 shows a schematic illustration of a measuring device and an object;

FIG. 7 shows a schematic illustration of movable units and an object;

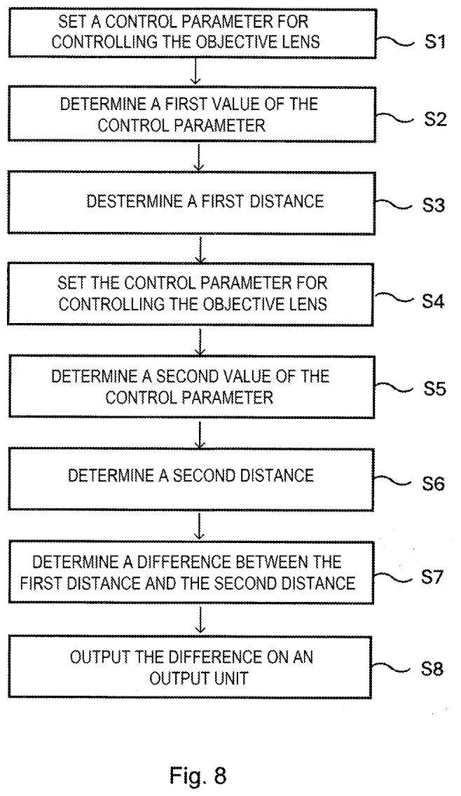

FIG. 8 shows a schematic illustration of a first embodiment of a method according to the invention;

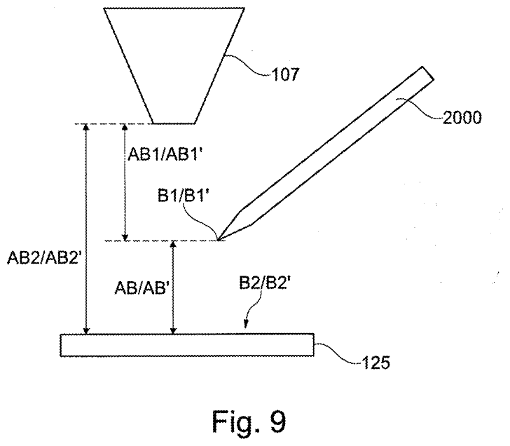

FIG. 9 shows a schematic illustration of a measuring device, an object and an objective lens;

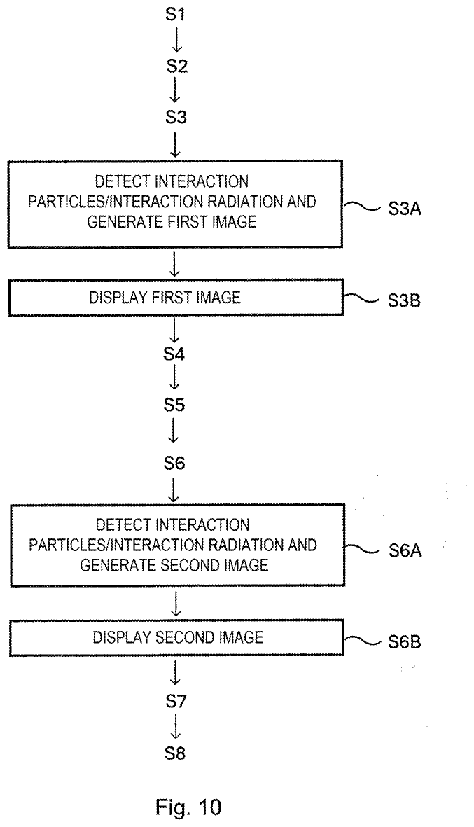

FIG. 10 shows a schematic illustration of a second embodiment of a method according to the invention;

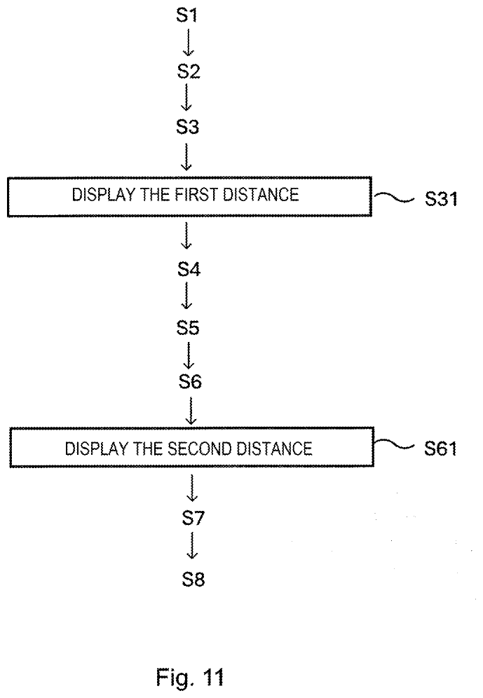

FIG. 11 shows a schematic illustration of a third embodiment of a method according to the invention;

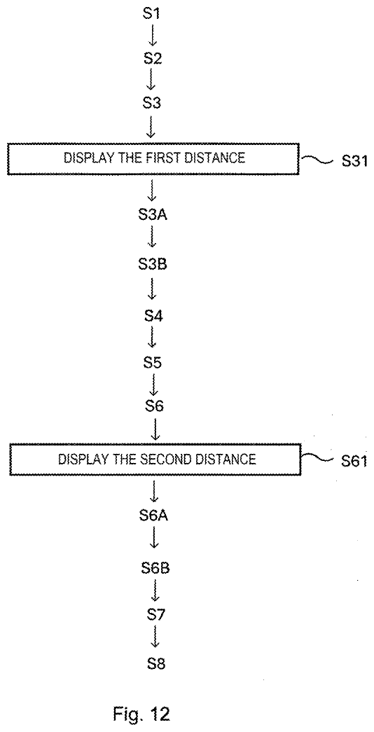

FIG. 12 shows a schematic illustration of a fourth embodiment of a method according to the invention;

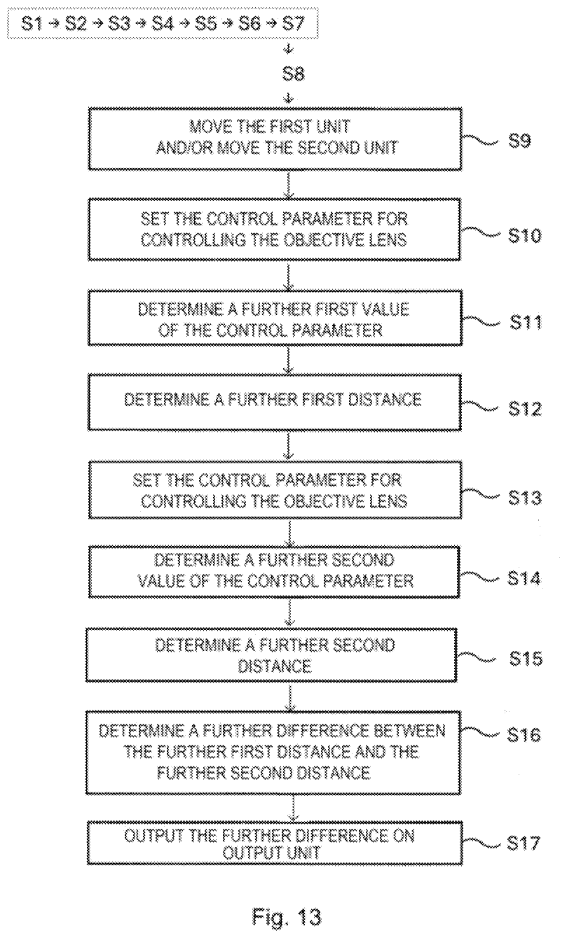

FIG. 13 shows a schematic illustration of a fifth embodiment of a method according to the invention;

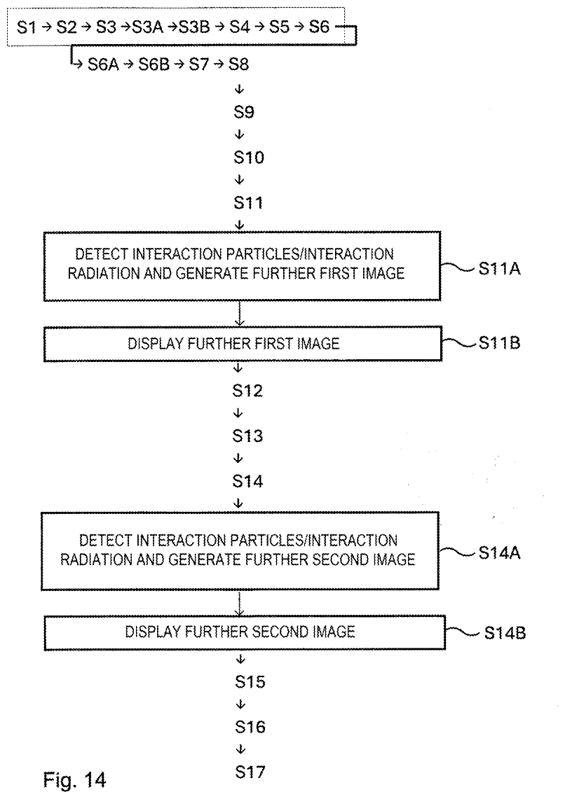

FIG. 14 shows a schematic illustration of a sixth embodiment of a method according to the invention;

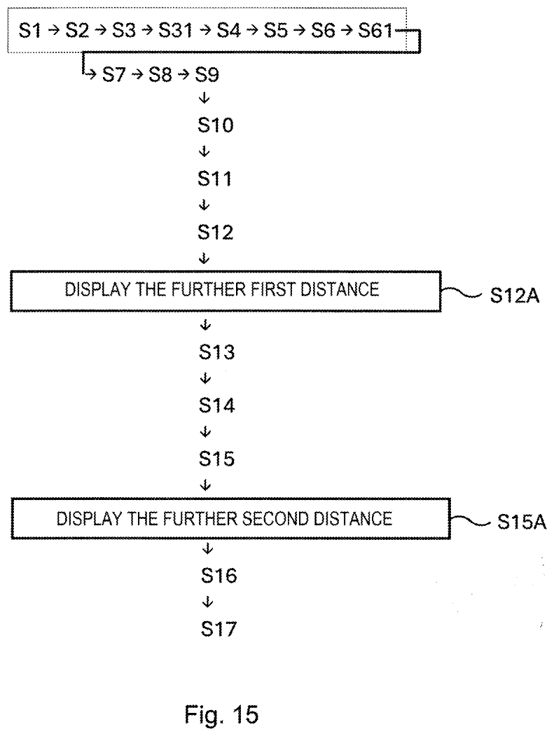

FIG. 15 shows a schematic illustration of a seventh embodiment of a method according to the invention; and

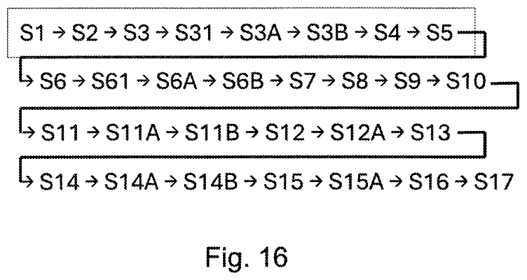

FIG. 16 shows a schematic illustration of an eighth embodiment of a method according to the invention.

The invention will now be explained in more detail by way of particle beam apparatuses in the form of an SEM and in the form of a combination apparatus comprising an electron beam column and an ion beam column. It is explicitly pointed out that the invention may be used in any particle beam apparatus, in particular in any electron beam apparatus and/or any ion beam apparatus.

FIG. 1 shows a schematic illustration of an SEM 100. The SEM 100 has a first beam generator in the form of an electron source 101 embodied as a cathode. Furthermore, the SEM 100 is provided with an extraction electrode 102 and with an anode 103, which is placed on one end of a beam guiding tube 104 of the SEM 100. By way of example, the electron source 101 is embodied as a thermal field emitter. However, the invention is not restricted to such an electron source 101. Rather, any electron source can be used.

Electrons emerging from the electron source 101 form a primary electron beam. The electrons are accelerated to anode potential owing to a potential difference between the electron source 101 and the anode 103. In the embodiment illustrated here, the anode potential is 100 V to 35 kV, for example 5 kV to 15 kV, in particular 8 kV, relative to an earth potential of a housing of a sample chamber 120. However, it could alternatively also be at earth potential.

Two condenser lenses, specifically a first condenser lens 105 and a second condenser lens 106, are arranged on the beam guiding tube 104. As viewed in the direction of a first objective lens 107 proceeding from the electron source 101, the first condenser lens 105 is arranged first in this case, followed by the second condenser lens 106. It is explicitly pointed out that further embodiments of the SEM 100 may comprise only a single condenser lens. A first aperture unit 108 is arranged between the anode 103 and the first condenser lens 105. Together with the anode 103 and the beam guiding tube 104, the first aperture unit 108 is at a high-voltage potential, specifically the potential of the anode 103, or connected to earth. The first aperture unit 108 has numerous first apertures 108A, one of which is illustrated in FIG. 1. For example, two first apertures 108A are present. Each of the numerous first apertures 108A has a different aperture diameter. By means of an adjusting mechanism (not illustrated), it is possible to adjust a desired first aperture 108A to an optical axis OA of the SEM 100. It is explicitly pointed out that, in further embodiments, the first aperture unit 108 can be provided only with a single aperture 108A. An adjusting mechanism may not be provided in this embodiment. The first aperture unit 108 is then stationary. A stationary second aperture unit 109 is arranged between the first condenser lens 105 and the second condenser lens 106. As an alternative thereto, provision is made for the second aperture unit 109 to be movable.

The first objective lens 107 has pole pieces 110, in which a drilled hole is formed. The beam guiding tube 104 is guided through this drilled hole. An electric coil 111 is arranged in the pole pieces 110.

An electrostatic retardation device is arranged in a lower region of the beam guiding tube 104. It comprises a single electrode 112 and a tube electrode 113. The tube electrode 113 is arranged at an end of the beam guiding tube 104 facing an object 125 arranged on a holding device 114 for the object 125.

Together with the beam guiding tube 104, the tube electrode 113 is at the potential of the anode 103, while the single electrode 112 and the object 125 are at a lower potential in relation to the potential of the anode 103. In the present case, this is the earth potential of the housing of the sample chamber 120. In this way, the electrons of the primary electron beam can be decelerated to a desired energy required for examining the object 125.

The SEM 100 furthermore comprises a scanning device 115, by means of which the primary electron beam can be deflected and scanned over the object 125. The scanning device 115 can be arranged inside and/or outside the pole pieces 110. The electrons of the primary electron beam interact with the object 125. The interaction results in interaction particles and/or interaction radiation which are/is detected. In particular, interaction particles are electrons that are emitted from the surface of the object 125—so-called secondary electrons—or electrons of the primary electron beam that are backscattered—so-called backscattered electrons. The interaction radiation will be discussed in more detail further below.

The object 125 and the single electrode 112 may also be at different potentials and potentials that differ from earth. This makes it possible to adjust the location of the retardation of the primary electron beam in relation to the object 125. For example, aberrations become smaller if the retardation is performed quite close to the object 125.

A detector arrangement having a first detector 116 and a second detector 117 is arranged in the beam guiding tube 104 to detect the secondary electrons and/or the backscattered electrons. In this case, the first detector 116 is arranged on the source side along the optical axis OA, while the second detector 117 is arranged on the object side along the optical axis OA in the beam guiding tube 104. The first detector 116 and the second detector 117 are arranged offset from one another in the direction of the optical axis OA of the SEM 100. Both the first detector 116 and the second detector 117 have a respective through-opening, through which the primary electron beam is able to pass. The first detector 116 and the second detector 117 are approximately at the potential of the anode 103 and the beam guiding tube 104. The optical axis OA of the SEM 100 runs through the respective through-openings.

The second detector 117 is used mainly to detect secondary electrons. Upon emergence from the object 125, the secondary electrons initially have a low kinetic energy and random directions of movement. The secondary electrons are accelerated in the direction of the first objective lens 107 by the strong extraction field that emanates from the tube electrode 113. The secondary electrons enter the first objective lens 107 approximately in a parallel fashion. The beam diameter of the beam of the secondary electrons remains small even in the first objective lens 107. The first objective lens 107 then has a strong effect on the secondary electrons and generates a comparatively short focus of the secondary electrons with sufficiently steep angles to the optical axis OA, and so the secondary electrons diverge significantly from one another downstream of the focus and are incident on the active area of the second detector 117. By contrast, only a small proportion of electrons backscattered at the object 125—that is to say backscattered electrons with a relatively high kinetic energy in comparison with the secondary electrons upon emergence from the object 125—are detected by the second detector 117. The high kinetic energy and the angles of the backscattered electrons to the optical axis OA upon emergence from the object 125 have the effect that a beam waist, that is to say a beam region of minimal diameter, of the backscattered electrons lies in the vicinity of the second detector 117. A large portion of the backscattered electrons pass through the through-opening of the second detector 117. Therefore, the first detector 116 substantially serves to detect the backscattered electrons.

In a further embodiment of the SEM 100, the first detector 116 may be additionally embodied with an opposing field grid 116A. The opposing field grid 116A is arranged on that side of the first detector 116 which is directed towards the object 125. With respect to the potential of the beam guiding tube 104, the opposing field grid 116A has a negative potential such that only backscattered electrons with high energy pass through the opposing field grid 116A to the first detector 116. Additionally or alternatively, the second detector 117 comprises a further opposing field grid, which is designed in a similar manner to the aforementioned opposing field grid 116A of the first detector 116 and has a similar function.

Furthermore, in the sample chamber 120, the SEM 100 has a chamber detector 119, for example an Everhart-Thornley detector or an ion detector, which has a metal-coated detection area that blocks light.

The detection signals generated by the first detector 116, the second detector 117 and the chamber detector 119 are used to generate an image or images of the surface of the object 125.

It is explicitly pointed out that the apertures of the first aperture unit 108 and of the second aperture unit 109 and also the through-openings of the first detector 116 and of the second detector 117 are illustrated in exaggerated fashion. The through-openings of the first detector 116 and of the second detector 117 have an extent perpendicular to the optical axis OA in the range of 0.5 mm to 5 mm. For example, they are circular and have a diameter in the range of 1 mm to 3 mm perpendicular to the optical axis OA.

The second aperture unit 109 is designed as a pinhole aperture unit in the embodiment illustrated here and is provided with a second aperture 118 for the passage of the primary electron beam, which has an extent in the range of 5 μm to 500 μm, for example 35 μm. As an alternative thereto, in a further embodiment, provision is made for the second aperture unit 109 to be provided with a plurality of apertures, which can be displaced mechanically with respect to the primary electron beam or which can be reached by the primary electron beam using electrical and/or magnetic deflection elements. For example, the second aperture unit 109 is embodied as a pressure stage aperture unit. This separates a first region, in which the electron source 101 is arranged and in which there is an ultra-high vacuum (10⁻⁷ hPa to 10⁻¹² hPa), from a second region, which has a high vacuum (10⁻³ hPa to 10⁻⁷ hPa). The second region is the intermediate pressure region of the beam guiding tube 104 leading to the sample chamber 120.

The sample chamber 120 is under vacuum. In order to generate the vacuum, a pump (not illustrated) is arranged on the sample chamber 120. In the embodiment illustrated in FIG. 1, the sample chamber 120 is operated in a first pressure range or in a second pressure range. The first pressure range comprises only pressures less than or equal to 10⁻³ hPa, and the second pressure range comprises only pressures greater than 10⁻³ hPa. The sample chamber 120 is vacuum-sealed in order to ensure these pressure ranges.

The holding device 114 is arranged on an object carrier in the form of an object stage 122. The object stage 122 is embodied so as to be movable in three directions arranged perpendicular to one another, specifically in an x-direction of the object stage 122 (first stage axis), in a y-direction of the object stage 122 (second stage axis) and in a z-direction of the object stage 122 (third stage axis). Moreover, the object stage 122 can be rotated about two axes of rotation of the object stage 122 (axes of rotation of the stage) which are arranged perpendicular to one another. The invention is not restricted to the object stage 122 described above. On the contrary, the object stage 122 may have further translation axes and axes of rotation, along which or about which the object stage 122 is able to move. This will be discussed again in greater detail further below.

The SEM 100 furthermore has a third detector 121 which is arranged in the sample chamber 120. More precisely, the third detector 121 is arranged downstream of the object stage 122, as viewed from the electron source 101 along the optical axis OA. The object stage 122 and hence the holding device 114 can be rotated in such a way that the primary electron beam can radiate through the object 125 arranged on the holding device 114. When the primary electron beam passes through the object 125 to be examined, the electrons of the primary electron beam interact with the material of the object 125 to be examined. The electrons passing through the object 125 to be examined are detected by the third detector 121.

A radiation detector 500 used to detect interaction radiation, for example x-ray radiation and/or cathodoluminescence, is arranged on the sample chamber 120. The radiation detector 500, the first detector 116, the second detector 117 and the chamber detector 119 are connected to a control unit 123 comprising a processor unit 127 and a monitor 124. For example, the monitor 124 is arranged on the control unit 123 and/or is connected to the control unit 123. The third detector 121, too, is connected to the control unit 123. This is not illustrated for reasons of clarity. The control unit 123 processes detection signals generated by the first detector 116, the second detector 117, the chamber detector 119, the third detector 121 and/or the radiation detector 500 and displays these detection signals in the form of images on the monitor 124.

The control unit 123 furthermore comprises a database 126, in which data are stored and from which data are read out.

The SEM 100 comprises a gas feed device 1000 with a gas feed unit 1001, which serves to feed a gas, for example a gaseous precursor substance, to a specific position on the surface of the object 125. Additionally or alternatively, the SEM 100 comprises an object holder in the form of a manipulator device 1000A with a manipulator 1001A, in which case the object 125 or a portion of the object 125 extracted from the object 125 (or a further object) can be arranged on the manipulator 1001A. Additionally or alternatively in turn, the SEM 100 comprises a measuring device 1000B having, for example, at least one tapering formation 1001B. The measuring device 1000B may preferably have a plurality of tapering formations 1001B which can be arranged at contact points of the object 125 in order to determine electrical and/or mechanical parameters of the object 125. The gas feed device 1000, the manipulator device 1000A and/or the measuring device 1000B will be discussed in more detail further below.

In the SEM 100, it is possible to adjust a distance A using the control unit 123 of the SEM 100. The distance A is given either (a) by an object distance between the single electrode 112 of the SEM 100 and the object 125 or (b) by a focal plane distance between the single electrode 112 of the SEM 100 and a focal plane of the first objective lens 107. The aforementioned distance A according to case (a) or case (b) is also referred to as the working distance. For example, the distance A in case (a) is adjusted by moving the object stage 122 and/or moving the first objective lens 107 using a movement device 128. For example, the distance A in case (b) is adjusted by varying an excitation of the first objective lens 107 along the optical axis OA of the SEM 100.

FIG. 2 shows a particle beam apparatus in the form of a combination apparatus 200. The combination apparatus 200 has two particle beam columns. Firstly, the combination apparatus 200 is provided with the SEM 100, as already illustrated in FIG. 1, albeit without the sample chamber 120. On the contrary, the SEM 100 is arranged on a sample chamber 201. The sample chamber 201 is under vacuum. In order to generate the vacuum, a pump (not illustrated) is arranged on the sample chamber 201. In the embodiment illustrated in FIG. 2, the sample chamber 201 is operated in a first pressure range or in a second pressure range. The first pressure range comprises only pressures less than or equal to 10⁻³ hPa, and the second pressure range comprises only pressures greater than 10⁻³ hPa. The sample chamber 201 is vacuum-sealed in order to ensure these pressure ranges.

Arranged in the sample chamber 201 is the chamber detector 119, which is embodied for example as an Everhart-Thornley detector or an ion detector and which comprises a metal-coated detection area that blocks light. Furthermore, the third detector 121 is arranged in the sample chamber 201.

The SEM 100 serves to generate a first particle beam, specifically the primary electron beam already described further above, and has the optical axis which has already been mentioned above, is provided with the reference sign 709 in FIG. 2 and is also referred to as the first beam axis below. Secondly, the combination apparatus 200 is provided with an ion beam apparatus 300, which is likewise arranged on the sample chamber 201. The ion beam apparatus 300 likewise has an optical axis, which is provided with the reference sign 710 in FIG. 2 and is also referred to as the second beam axis below.

The SEM 100 is arranged vertically in relation to the sample chamber 201. By contrast, the ion beam apparatus 300 is arranged in a manner inclined by an angle of approximately 0° to 90° with respect to the SEM 100. An arrangement of approximately 50° is illustrated by way of example in FIG. 2. The ion beam apparatus 300 has a second beam generator in the form of an ion beam generator 301. Ions that form a second particle beam in the form of an ion beam are generated by the ion beam generator 301. The ions are accelerated by way of an extraction electrode 302 at a predefinable potential. The second particle beam then passes through an ion optical unit of the ion beam apparatus 300, the ion optical unit having a condenser lens 303 and a second objective lens 304. The second objective lens 304 ultimately generates an ion probe, which is focused onto the object 125 arranged on a holding device 114. The holding device 114 is arranged on an object stage 122.

An adjustable or selectable aperture unit 306, a first electrode arrangement 307 and a second electrode arrangement 308 are arranged above the second objective lens 304 (that is to say in the direction of the ion beam generator 301), with the first electrode arrangement 307 and the second electrode arrangement 308 being embodied as scanning electrodes. The second particle beam is scanned over the surface of the object 125 by way of the first electrode arrangement 307 and the second electrode arrangement 308, with the first electrode arrangement 307 acting in a first direction and the second electrode arrangement 308 acting in a second direction opposite the first direction. Hence, the scanning is carried out for example in an x-direction. The scanning in a y-direction perpendicular thereto is effected by further electrodes (not illustrated), which are rotated by 90°, on the first electrode arrangement 307 and on the second electrode arrangement 308.

As explained above, the holding device 114 is arranged on the object stage 122. In the embodiment shown in FIG. 2, too, the object stage 122 is embodied so as to be movable in three directions arranged perpendicular to one another, specifically in an x-direction of the object stage 122 (first stage axis), in a y-direction of the object stage 122 (second stage axis) and in a z-direction of the object stage 122 (third stage axis). Moreover, the object stage 122 may be rotated about two axes of rotation (axes of rotation of the stage) which are arranged perpendicular to one another.

The distances illustrated in FIG. 2 between the individual units of the combination apparatus 200 are illustrated in exaggerated fashion in order to better illustrate the individual units of the combination apparatus 200.

A radiation detector 500 used to detect interaction radiation, for example x-ray radiation and/or cathodoluminescence, is arranged on the sample chamber 201. The radiation detector 500 is connected to a control unit 123 comprising a processor unit 127 and a monitor 124. For example, the monitor 124 is arranged on the control unit 123 and/or is connected to the control unit 123. The control unit 123 processes detection signals generated by the first detector 116 (not illustrated in FIG. 2), the second detector 117 (not illustrated in FIG. 2), the chamber detector 119, the third detector 121 and/or the radiation detector 500 and displays said detection signals in the form of images on the monitor 124.

The control unit 123 furthermore comprises a database 126, in which data are stored and from which data are read out.

The combination apparatus 200 comprises a gas feed device 1000 with a gas feed unit 1001, which serves to feed a gas, for example a gaseous precursor substance, to a specific position on the surface of the object 125. Additionally or alternatively, the combination apparatus 200 comprises an object holder in the form of a manipulator device 1000A with a manipulator 1001A, in which case the object 125 or a portion of the object 125 extracted from the object 125 (or a further object) can be arranged on the manipulator 1001A. Additionally or alternatively in turn, the SEM 100 comprises a measuring device 1000B having, for example, at least one tapering formation 1001B. The measuring device 1000B may preferably have a plurality of tapering formations 1001B which can be arranged at contact points of the object 125 in order to determine electrical and/or mechanical parameters of the object 125. The gas feed device 1000, the manipulator device 1000A and/or the measuring device 1000B will be discussed in more detail further below.

In the combination apparatus 200, too, it is possible to adjust working distances. It is possible in the SEM 100, for example, to adjust a distance A1 using the control unit 123. The distance A1 is given either (a) by an object distance between an outer boundary of the first objective lens 107 of the SEM 100 and the object 125 or (b) by a focal plane distance between the outer boundary of the first objective lens 107 of the SEM 100 and a focal plane of the first objective lens 107. The aforementioned distance A1 according to case (a) or case (b) is also referred to as the working distance. For example, the distance A1 in case (a) is adjusted by moving the object stage 122 and/or moving the first objective lens 107 using the movement device 128. For example, the distance A1 in case (b) is adjusted by varying an excitation of the first objective lens 107 along the first beam axis 709 of the SEM 100. It is furthermore possible to adjust a distance A2 using the control device 123. The distance A2 is given either (a) by an object distance between an outer boundary of the second objective lens 304 of the ion beam apparatus 300 and the object 125 or (b) by a focal plane distance between the outer boundary of the second objective lens 304 of the ion beam apparatus 300 and a focal plane of the second objective lens 304. The aforementioned distance A2 according to case (a) or case (b) is also referred to as the working distance. For example, the distance A2 in case (a) is adjusted by moving the object stage 122 and/or moving the second objective lens 304 using a movement device 128. For example, the distance A2 in case (b) is adjusted by varying an excitation of the second objective lens 304 along the second beam axis 710 of the ion beam apparatus 300.

FIG. 3 is a schematic illustration of a further embodiment of a particle beam apparatus according to the invention. This embodiment of the particle beam apparatus is provided with the reference sign 400 and comprises a mirror corrector for correcting chromatic and/or spherical aberration, for example. The particle beam apparatus 400 comprises a particle beam column 401, which is embodied as an electron beam column and which substantially corresponds to an electron beam column of a corrected SEM. However, the particle beam apparatus 400 is not restricted to an SEM with a mirror corrector. Rather, the particle beam apparatus 400 can comprise any type of corrector units.

The particle beam column 401 comprises a particle beam generator in the form of an electron source 402 (cathode), an extraction electrode 403 and an anode 404. For example, the electron source 402 is embodied as a thermal field emitter. Electrons emerging from the electron source 402 are accelerated to the anode 404 owing to a potential difference between the electron source 402 and the anode 404. Accordingly, a particle beam in the form of an electron beam is formed along a first optical axis OA1.

The particle beam is guided along a beam path that corresponds to the first optical axis OA1 after the particle beam has emerged from the electron source 402. A first electrostatic lens 405, a second electrostatic lens 406 and a third electrostatic lens 407 are used to guide the particle beam.

Furthermore, the particle beam is adjusted along the beam path using a beam guiding device. The beam guiding device in this embodiment comprises a source adjusting unit with two magnetic deflection units 408 arranged along the first optical axis OA1. Moreover, the particle beam apparatus 400 comprises electrostatic beam deflection units. A first electrostatic beam deflection unit 409, which is also embodied as a quadrupole in a further embodiment, is arranged between the second electrostatic lens 406 and the third electrostatic lens 407. The first electrostatic beam deflection unit 409 is likewise arranged downstream of the magnetic deflection units 408. A first multi-pole unit 409A in the form of a first magnetic deflection unit is arranged on one side of the first electrostatic beam deflection unit 409. Moreover, a second multi-pole unit 409B in the form of a second magnetic deflection unit is arranged on the other side of the first electrostatic beam deflection unit 409. The first electrostatic beam deflection unit 409, the first multi-pole unit 409A and the second multi-pole unit 409B are adjusted for the purpose of adjusting the particle beam in relation to the axis of the third electrostatic lens 407 and the entrance window of a beam deflection device 410. The first electrostatic beam deflection unit 409, the first multi-pole unit 409A and the second multi-pole unit 409B may interact like a Wien filter. A further magnetic deflection element 432 is arranged at the entrance to the beam deflection device 410.

The beam deflection device 410 is used as a particle beam deflector, which deflects the particle beam in a specific manner. The beam deflection device 410 comprises a plurality of magnetic sectors, specifically a first magnetic sector 411A, a second magnetic sector 411B, a third magnetic sector 411C, a fourth magnetic sector 411D, a fifth magnetic sector 411E, a sixth magnetic sector 411F and a seventh magnetic sector 411G. The particle beam enters the beam deflection device 410 along the first optical axis OA1 and is deflected by the beam deflection device 410 in the direction of a second optical axis OA2. The beam is deflected by an angle of 30° to 120° by way of the first magnetic sector 411A, by way of the second magnetic sector 411B and by way of the third magnetic sector 411C. The second optical axis OA2 is oriented at the same angle with respect to the first optical axis OA1. The beam deflection device 410 also deflects the particle beam that is guided along the second optical axis OA2, to be precise in the direction of a third optical axis OA3. The beam deflection is provided by the third magnetic sector 411C, the fourth magnetic sector 411D and the fifth magnetic sector 411E. In the embodiment in FIG. 3, the deflection with respect to the second optical axis OA2 and with respect to the third optical axis OA3 is provided by deflecting the particle beam at an angle of 90°. Hence, the third optical axis OA3 runs coaxially with the first optical axis OA1. However, it is pointed out that the particle beam apparatus 400 according to the invention described here is not restricted to deflection angles of 90°. On the contrary, any suitable deflection angle by the beam deflection device 410 may be chosen, for example 70° or 110°, with the result that the first optical axis OA1 does not run coaxially with the third optical axis OA3. With regard to further details of the beam deflection device 410, reference is made to WO 2002/067286 A2.

After the particle beam has been deflected by the first magnetic sector 411A, the second magnetic sector 411B and the third magnetic sector 411C, the particle beam is guided along the second optical axis OA2. The particle beam is guided to an electrostatic mirror 414 and travels on its way to the electrostatic mirror 414 along a fourth electrostatic lens 415, a third multi-pole unit 416A in the form of a magnetic deflection unit, a second electrostatic beam deflection unit 416, a third electrostatic beam deflection unit 417 and a fourth multi-pole unit 416B in the form of a magnetic deflection unit. The electrostatic mirror 414 comprises a first mirror electrode 413A, a second mirror electrode 413B and a third mirror electrode 413C. Electrons of the particle beam that are reflected back at the electrostatic mirror 414 once again travel along the second optical axis OA2 and re-enter the beam deflection device 410. Then, they are deflected to the third optical axis OA3 by the third magnetic sector 411C, the fourth magnetic sector 411D and the fifth magnetic sector 411E.

The electrons of the particle beam emerge from the beam deflection device 410 and are guided along the third optical axis OA3 to an object 425 that is intended to be examined and is arranged in a holding device 114. On the way to the object 425, the particle beam is guided to a fifth electrostatic lens 418, a beam guiding tube 420, a fifth multi-pole unit 418A, a sixth multi-pole unit 418B and an objective lens 421. The fifth electrostatic lens 418 is an electrostatic immersion lens. By way of the fifth electrostatic lens 418, the particle beam is decelerated or accelerated to an electrical potential of the beam guiding tube 420.

By way of the objective lens 421, the particle beam is focused into a focal plane in which the object 425 is arranged. The holding device 114 is arranged on a movable object stage 424. The movable object stage 424 is arranged in a sample chamber 426 of the particle beam apparatus 400. The object stage 424 is embodied so as to be movable in three directions arranged perpendicular to one another, specifically in an x-direction of the object stage 424 (first stage axis), in a y-direction of the object stage 424 (second stage axis) and in a z-direction of the object stage 424 (third stage axis). Moreover, the object stage 424 may be rotated about two axes of rotation (axes of rotation of the stage) which are arranged perpendicular to one another. This will be discussed again in greater detail further below.

The sample chamber 426 is under vacuum. In order to generate the vacuum, a pump (not illustrated) is arranged on the sample chamber 426. In the embodiment illustrated in FIG. 3, the sample chamber 426 is operated in a first pressure range or in a second pressure range. The first pressure range comprises only pressures less than or equal to 10⁻³ hPa, and the second pressure range comprises only pressures greater than 10⁻³ hPa. The sample chamber 426 is vacuum-sealed in order to ensure these pressure ranges.

The objective lens 421 may be embodied as a combination of a magnetic lens 422 and a sixth electrostatic lens 423. The end of the beam guiding tube 420 may furthermore be an electrode of an electrostatic lens. After emerging from the beam guiding tube 420, particles of the particle beam apparatus are decelerated to a potential of the object 425. The objective lens 421 is not restricted to a combination of the magnetic lens 422 and the sixth electrostatic lens 423. On the contrary, the objective lens 421 may assume any suitable form. For example, the objective lens 421 may also be embodied as a purely magnetic lens or as a purely electrostatic lens.

The particle beam that is focused onto the object 425 interacts with the object 425. Interaction particles and/or interaction radiation are/is generated. In particular, secondary electrons are emitted from the object 425 or backscattered electrons are backscattered at the object 425. The secondary electrons or the backscattered electrons are accelerated again and guided into the beam guiding tube 420 along the third optical axis OA3. In particular, the trajectories of the secondary electrons and of the backscattered electrons travel on the route of the beam path of the particle beam in the opposite direction to the particle beam.

The particle beam apparatus 400 comprises a first analysis detector 419, which is arranged between the beam deflection device 410 and the objective lens 421 along the beam path. Secondary electrons travelling in directions oriented at a large angle with respect to the third optical axis OA3 are detected by the first analysis detector 419.

Backscattered electrons and secondary electrons which are at a small axial distance with respect to the third optical axis OA3 at the location of the first analysis detector 419—i.e. backscattered electrons and secondary electrons which are at a small distance from the third optical axis OA3 at the location of the first analysis detector 419—enter the beam deflection device 410 and are deflected along a detection beam path 427 to a second analysis detector 428 by the fifth magnetic sector 411E, the sixth magnetic sector 411F and the seventh magnetic sector 411G. For example, the deflection angle is 90°or 110°.

The first analysis detector 419 generates detection signals that are largely generated by emitted secondary electrons. The detection signals generated by the first analysis detector 419 are guided to a control unit 123 and are used to obtain information about the properties of the region of interaction of the focused particle beam with the object 425. In particular, the focused particle beam is scanned over the object 425 using a scanning device 429. By way of the detection signals generated by the first analysis detector 419, an image of the scanned region of the object 425 is then able to be generated and displayed on a presentation unit. The presentation unit is, for example, a monitor 124 which is arranged on the control unit 123 and/or is connected to the control unit 123.

The second analysis detector 428 is also connected to the control unit 123. Detection signals from the second analysis detector 428 are guided to the control unit 123 and used to generate an image of the scanned region of the object 425 and to display it on a presentation unit. The presentation unit is, for example, the monitor 124 which is arranged on the control unit 123 and/or is connected to the control unit 123.

A radiation detector 500 used to detect interaction radiation, for example x-ray radiation and/or cathodoluminescence, is arranged on the sample chamber 426. The radiation detector 500 is connected to the control unit 123 comprising a processor unit 127 and the monitor 124. Additionally or alternatively, the control unit 123 is connected to the monitor 124. The control unit 123 processes detection signals from the radiation detector 500 and displays them in the form of images on the monitor 124.

The control unit 123 furthermore comprises a database 126, in which data are stored and from which data are read out.

The particle beam apparatus 400 comprises a gas feed device 1000 with a gas feed unit 1001, which serves to feed a gas, for example a gaseous precursor substance, to a specific position on the surface of the object 425. Additionally or alternatively, the particle beam apparatus 400 comprises an object holder in the form of a manipulator device 1000A with a manipulator 1001A, in which case the object 425 or a portion of the object 425 extracted from the object 425 (or a further object) can be arranged on the manipulator 1001A. Additionally or alternatively in turn, the SEM 100 comprises a measuring device 1000B having, for example, at least one tapering formation 1001B. The measuring device 1000B may preferably have a plurality of tapering formations 1001B which can be arranged at contact points of the object 425 in order to determine electrical and/or mechanical parameters of the object 425. The gas feed device 1000, the manipulator device 1000A and/or the measuring device 1000B will be discussed in more detail further below.

In the particle beam apparatus 400, it is possible to adjust a distance A using the control unit 123 of the particle beam apparatus 400. The distance A is given either (a) by an object distance between an outer boundary of the objective lens 421 of the particle beam apparatus 400 and the object 425 or (b) by a focal plane distance between the outer boundary of the objective lens 421 of the particle beam apparatus 400 and a focal plane of the objective lens 421. The aforementioned distance A according to case (a) or case (b) is also referred to as the working distance. For example, the distance A in case (a) is adjusted by moving the object stage 424 and/or moving the objective lens 421 using a movement device 128. For example, the distance A in case (b) is adjusted by varying an excitation of the objective lens 421 along the optical axis OA3 of the particle beam apparatus 400.

The SEM 100, the combination apparatus 200 and also the particle beam apparatus 400 comprise a plurality of movable units (in particular assemblies) which are movable by way of a movement device, for example. This will be discussed in greater detail below.

As explained above, the SEM 100 and the combination apparatus 200 comprise a holding device 114 for holding the object 125. The holding device 114 is arranged on a movable assembly in the form of the object stage 122. The particle beam apparatus 400 likewise comprises the holding device 114 for holding the object 425. The holding device 114 of the particle beam apparatus 400 is arranged on a movable assembly in the form of the movable object stage 424. The object stages 122 and 424 and also the movement devices thereof will be discussed in greater detail below.

The object stage 122, 424 is embodied as a movable object stage, which is illustrated schematically in FIGS. 4 and 5. It is pointed out that the invention is not restricted to the object stage 122, 424 described here. On the contrary, the invention may include any movable object stage suitable for the invention. The holding device 114 is arranged on the object stage 122, 424. The object stage 122, 424 comprises movement elements of a movement device that ensures a movement of the object stage 122, 424 in such a way that a region of interest on the object 125, 425 can be examined, for example by means of a particle beam. The movement elements are illustrated schematically in FIGS. 4 and 5 and are explained below.

The object stage 122, 424 has a first movement element 600, which for example is arranged on a housing 601 of the sample chamber 120, 201 or 426, in which in turn the object stage 122, 424 is arranged. The first movement element 600 enables a movement of the object stage 122, 424 along the z-axis of the object stage 122, 424 (third stage axis). Furthermore, a second movement element 602 is provided. The second movement element 602 enables a rotation of the object stage 122, 424 about a first axis of rotation 603 of the stage of the object stage 122, 424, which is also referred to as a tilt axis. This second movement element 602 serves to tilt the object 125, 425 about the first axis of rotation 603 of the stage of the object stage 122, 424, wherein the object 125, 425 is arranged on the holding device 114.

Arranged on the second movement element 602, in turn, is a third movement element 604 which is embodied as a guide for a slide and ensures that the object stage 122, 424 is movable in the x-direction of the object stage 122, 424 (first stage axis). The abovementioned slide is in turn a further movement element, specifically a fourth movement element 605. The fourth movement element 605 is embodied such that the object stage 122, 424 is movable in the y-direction of the object stage 122, 424 (second stage axis). For this purpose, the fourth movement element 605 comprises a guide in which a further slide is guided, the holding device 114 in turn being arranged on the latter.

The holding device 114 is in turn provided with a fifth movement element 606 which makes it possible to rotate the holding device 114 about a second axis of rotation 607 of the stage of the object stage 122, 424. The second axis of rotation 607 of the stage of the object stage 122, 424 is oriented perpendicular to the first axis of rotation 603 of the stage of the object stage 122, 424.

On account of the above-described arrangement, the object stage 122, 424 of the embodiment discussed here has the following kinematic chain: First movement element 600 (movement along the z-axis of the object stage 122, 424)—second movement element 602 (rotation about the first axis of rotation 603 of the stage of the object stage 122, 424)—third movement element 604 (movement along the x-axis of the object stage 122, 424)—fourth movement element 605 (movement along the y-axis of the object stage 122, 424)—fifth movement element 606 (rotation about the second axis of rotation 607 of the stage of the object stage 122, 424). Additionally or alternatively, other kinematic chains may also be realized.

In a further embodiment (not illustrated), provision is made for further movement elements to be arranged on the object stage 122, 424 such that movements along further translational axes and/or about further axes of rotation are made possible.

As is evident from FIG. 5, each of the aforementioned movement elements is connected to a drive unit in the form of a motor M1 to M5. In this regard, the first movement element 600 is connected to a first drive unit M1 and is driven owing to a driving force that is provided by the first drive unit M1. The second movement element 602 is connected to a second drive unit M2, which drives the second movement element 602. The third movement element 604 is connected in turn to a third drive unit M3. The third drive unit M3 provides a driving force for driving the third movement element 604. The fourth movement element 605 is connected to a fourth drive unit M4, with the fourth drive unit M4 driving the fourth movement element 605. Furthermore, the fifth movement element 606 is connected to a fifth drive unit M5. The fifth drive unit M5 provides a driving force that drives the fifth movement element 606.

The abovementioned drive units M1 to M5 may be embodied as stepper motors, for example, and are controlled by a drive control unit 608 and are each supplied with a supply current by the drive control unit 608 (cf. FIG. 5). It is explicitly pointed out that the invention is not restricted to the movement by means of stepper motors. Rather, any drive units, such as brushless motors and/or piezoelectric drives, can be used as drive units.

As explained above, the SEM 100, the combination apparatus 200 and also the particle beam apparatus 400 comprise the gas feed device 1000 with the gas feed unit 1001, which serves to feed a gas, for example a gaseous precursor substance, to a specific position on the surface of the object 125, 425. For example, the gas feed unit 1001 is embodied as a cannula and/or is acicular. In particular, the gas feed unit 1001 has a feed opening, the diameter of which is for example in the range of 10 μm to 1000 μm, in particular in the range of 400 μm to 600 μm. The gas feed unit 1001 is likewise a movable assembly that is movable by means of a movement device. In accordance with FIGS. 1 to 3, the gas feed device 1000 comprises a first movement unit 1002, a second movement unit 1003 and a third movement unit 1004. By way of example, the first movement unit 1002, the second movement unit 1003 and the third movement unit 1004 are embodied as stepper motors and/or piezoelectric drives. Owing to the first movement unit 1002, the second movement unit 1003 and the third movement unit 1004, the gas feed unit 1001 is embodied so as to be movable in three directions arranged perpendicular to one another, for example, specifically in an x-direction of the gas feed unit 1001 by means of the first movement unit 1002, in a y-direction of the gas feed unit 1001 by means of the second movement unit 1003 and in a z-direction of the gas feed unit 1001 by means of the third movement unit 1004. Moreover, the gas feed unit 1001 can be rotated for example about two axes of rotation of the gas feed unit 1001 which are arranged in particular perpendicular to one another (not illustrated in FIGS. 1 to 3). Furthermore, the gas feed unit 1001 can be rotated, for example, about a longitudinal axis of the gas feed unit 1001.

As explained above, the SEM 100, the combination apparatus 200 and also the particle beam apparatus 400 additionally or alternatively comprise an object holder in the form of the manipulator device 1000A with the manipulator 1001A. The manipulator 1001A is, for example, acicular and/or tapering. Additionally or alternatively, provision is made for the manipulator 1001A to be embodied with a gripping device. The object 125, 425 or a portion of the object 125, 425 extracted from the object 125, 425 (or any other object) can be arranged on the manipulator 1001A. The manipulator 1001A is likewise a movable assembly that is movable by means of a movement device. In accordance with FIGS. 1 to 3, the manipulator device 1000A comprises a first movement unit 1002A, a second movement unit 1003A and a third movement unit 1004A. By way of example, the first movement unit 1002A, the second movement unit 1003A and the third movement unit 1004A are embodied as stepper motors and/or piezoelectric drives. Owing to the first movement unit 1002A, the second movement unit 1003A and the third movement unit 1004A, the manipulator 1001A is embodied so as to be movable for example in three directions arranged perpendicular to one another, specifically in an x-direction of the manipulator 1001A by means of the first movement unit 1002A, in a y-direction of the manipulator 1001A by means of the second movement unit 1003A and in a z-direction of the manipulator 1001A by means of the third movement unit 1004A. Moreover, the manipulator 1001A can be rotated for example about two axes of rotation of the manipulator 1001A which are arranged in particular perpendicular to one another (not illustrated in FIGS. 1 to 3). Furthermore, the manipulator 1001A can be rotated, for example, about a longitudinal axis of the manipulator 1001A.

As explained above, the SEM 100, the combination apparatus 200 and also the particle beam apparatus 400 additionally or alternatively comprise a measuring device 1000B having at least one tapering formation 1001B, for example. In particular, the measuring device 1000B is designed to make electrical contact and/or to make mechanical contact and/or to dissipate electrical current and/or to supply electrical current and/or to measure an electrical potential and/or to supply an electrical potential. The measuring device 1001B may preferably have a plurality of tapering formations 1001B. The tapering formation(s) 1001B can be arranged at contact points of the object 125, 425 in order to determine electrical and/or mechanical parameters of the object 125, 425. The tapering formation 1001B is likewise a movable assembly that is movable by means of a movement device. The statements made above and below also apply if a plurality of tapering formations 1001B are included. According to FIGS. 1 to 3, the tapering formation 1001B or each or at least one of the tapering formations 1001B respectively comprises a first movement unit 1002B, a second movement unit 1003B and a third movement unit 1004B. By way of example, the first movement unit 1002B, the second movement unit 1003B and the third movement unit 1004B are embodied as stepper motors and/or piezoelectric drives. Owing to the first movement unit 1002B, the second movement unit 1003B and the third movement unit 1004B, the tapering formation 1001B or each or at least one of the tapering formations 1001B is embodied so as to be movable in three directions arranged perpendicular to one another, for example, specifically in an x-direction of the tapering formation 1001B by means of the first movement unit 1002B, in a y-direction of the tapering formation 1001B by means of the second movement unit 1003B and in a z-direction of the tapering formation 1001B by means of the third movement unit 1004B. In addition, the tapering formation 1001B or each or at least one of the tapering formations 1001B can be rotated for example about two axes of rotation arranged perpendicular to one another (not illustrated in FIGS. 1 to 3). Furthermore, the tapering formation 1001B or each or at least one of the tapering formations 1001B may be rotated about a longitudinal axis of the tapering formation 1001B.

FIG. 6 shows a schematic illustration of the measuring device 1000B and the object 125, 425 from the direction of the electron source 101, 402. The measuring device 1000B has a plurality of tapering formations which, instead of being provided with the reference sign 1001B, are provided with different reference signs. FIG. 6 illustrates, by way of example, three tapering formations, specifically a first tapering formation 2000, a second tapering formation 2001 and a third tapering formation 2002. Each of the aforementioned tapering formations 2000, 2001, 2002 can be arranged at a respective contact point on the surface of the object 125, 425. Reference is made to the explanations given above, which also apply here.

As explained above, the SEM 100, the combination apparatus 200 and also the particle beam apparatus 400 additionally or alternatively comprise a movable detector. By way of example, the movable detector is embodied as the chamber detector 119 or the radiation detector 500. The movable detector is movable by means of a movement device. By way of example, the movable detector is moved by a first detector movement unit (not illustrated), a second detector movement unit (not illustrated) and a third detector movement unit (not illustrated), which are embodied in particular analogously to the movement units explained further above. By way of example, the first detector movement unit, the second detector movement unit and the third detector movement unit are embodied as stepper motors and/or piezoelectric drives. Owing to the first detector movement unit, the second detector movement unit and the third detector movement unit, the movable detector is embodied so as to be movable for example in three directions arranged perpendicular to one another, specifically in an x-direction of the movable detector by means of the first detector movement unit, in a y-direction of the movable detector by means of the second detector movement unit and in a z-direction of the movable detector by means of the third detector movement unit. Moreover, the movable detector can be rotated for example about in particular two axes of rotation of the movable detector which are arranged perpendicular to one another. Furthermore, the movable detector can be rotated about a longitudinal axis of the movable detector.

FIG. 7 shows a schematic illustration of the object 125, 425 and the gas feed unit 1001, the manipulator 1001A and/or the tapering formation 1001B. In order to lead the gas feed unit 1001, the manipulator 1001A and/or the tapering formation 1001B to the object 125, 425, it is desirable to know as precisely as possible a distance AB between the object 125, 425 and the gas feed unit 1001, the manipulator 1001A and/or the tapering formation 1001B.

Embodiments of the method according to the invention will now be discussed below. This will be explained by way of example on the basis of the SEM 100 in accordance with FIG. 1. The explanations given below in respect of the SEM 100 apply, mutatis mutandis, with regard to the embodiments of the method according to the invention in respect of the combination apparatus 200 and/or the particle beam apparatus 400. Furthermore, the embodiments of the method according to the invention are explained with reference to the measuring device 1000B. The explanations given below in respect of the measuring device 1000B apply, mutatis mutandis, with regard to the gas feed device 1000, the manipulator device 1000A, the movable object stage 122, 424 and/or the movable detector 119, 500.

FIG. 8 shows a first embodiment of the method according to the invention. The method explained below can be carried out jointly for all tapering formations 1001B, 2000, 2001, 2002 or individually in each case for each tapering formation 1001B, 2000, 2001, 2002 or jointly for at least two tapering formations of the tapering formations 1001B, 2000, 2001, 2002. The method according to the invention is explained by way of example below for a single tapering formation of the tapering formations 1001B, 2000, 2001, 2002, specifically the first tapering formation 2000. The following explanations also apply to the implementation of the method jointly for all tapering formations 1001B, 2000, 2001, 2002 and/or jointly for at least two tapering formations 1001B, 2000, 2001, 2002.

FIG. 9 shows a schematic illustration of the first objective lens 107, the object 125 and the first tapering formation 2000. In order to lead the first tapering formation 2000 to the object 125, it is desirable to know as precisely as possible the distance AB between the object 125 and the first tapering formation 2000.

In a method step S1 of the embodiment according to FIG. 8, a control parameter for controlling the first objective lens 107 of the SEM 100 is set using the control unit 123 in such a way that the primary electron beam of the SEM 100 is focused onto a first region B1 of the first tapering formation 2000 using the first objective lens 107 (cf. FIG. 9). In this case, the first region B1 is arranged, for example, at a tip of the first tapering formation 2000. The aforementioned control parameter is, for example, a control current or a control voltage. The first setting of the control parameter comprises, for example, setting the control parameter in such a way that the first region B1 of the first tapering formation 2000 is arranged in a first focal plane of the first objective lens 107. Additionally or alternatively, provision is made for the first setting of the control parameter to comprise setting the control parameter to an arbitrary value. Furthermore, the first tapering formation 2000 is arranged by moving the first tapering formation 2000 in a focal plane of the first objective lens 107 determined by the arbitrary value of the control parameter.

In a method step S2 of the embodiment according to FIG. 8, a first value of the control parameter, for which the primary electron beam is focused onto the first region B1 of the first tapering formation 2000, is determined using the processor unit 127.

In a method step S3 of the embodiment according to FIG. 8, a first distance AB1 (cf. FIG. 9) between the outer boundary of the first objective lens 107 and the first region B1 of the first tapering formation 2000 is determined using the first value of the control parameter and the processor unit 127 (cf. FIG. 9). Basically, the first distance AB1 is the focal plane distance which is also referred to as the working distance. For example, the first distance AB1 is a shortest connection of all possible connections between any point on the outer boundary of the first objective lens 107 and the first region B1 of the first tapering formation 2000.

In a method step S4 of the embodiment according to FIG. 8, second setting of the control parameter for controlling the first objective lens 107 is carried out using the control unit 123 in such a way that the primary electron beam is focused onto a second region B2 of the object 125 (cf. FIG. 9) using the first objective lens 107. The second setting of the control parameter comprises, for example, setting the control parameter in such a way that the second region B2 of the object 125 is arranged in a second focal plane of the first objective lens 107. Additionally or alternatively, provision is made for the second setting of the control parameter to comprise setting the control parameter to a further arbitrary value. Furthermore, the object 125 is arranged by moving the object 125 by means of the object stage 122 in a focal plane of the first objective lens 107 determined by the further arbitrary value.

In a method step S5 of the embodiment according to FIG. 8, a second value of the control parameter, for which the primary electron beam is focused onto the second region B2 of the object 125, is determined using the processor unit 127.

In a method step S6 of the embodiment according to FIG. 8, a second distance AB2 between the outer boundary of the first objective lens 107 and the second region B2 of the object 125 is determined using the second value of the control parameter and the processor unit 127 of the SEM 100. Basically, the second distance AB2 is also a focal plane distance which is also referred to as the working distance. For example, the second distance is a shortest connection of all possible connections between any point on the outer boundary of the first objective lens 107 and the second region B2 of the object 125.

In a method step S7 of the embodiment according to FIG. 8, a difference between the first distance AB1 and the second distance AB2 is determined using the processor unit 127.

Furthermore, in a method step S8, provision is made for the difference and/or the absolute value of the difference to be output on the monitor 124 of the SEM 100. This is effected for example by displaying a numerical value and/or by displaying a colour code and/or by displaying a 3D representation representing the difference and/or by displaying the difference and/or the absolute value of the difference with a pointer and/or by displaying a flashing frequency and/or by displaying a brightness. Additionally or alternatively, the difference and/or the absolute value of the difference is/are acoustically output, for example, by a sound frequency and/or a pitch and/or a pulse frequency and/or a sequence of sounds using a loudspeaker. Basically, the difference and/or the absolute value of the difference correspond(s) to the distance AB between the first tapering formation 2000 and the object 125.

FIG. 10 shows a further embodiment of the method according to the invention. The embodiment according to FIG. 10 is based on the embodiment according to FIG. 8. Reference is made to the explanations given above, which also apply here. In contrast to the embodiment according to FIG. 8, the embodiment according to FIG. 10 has a method step S3A, for example after method step S3. In method step S3A, when the primary electron beam is focused onto the first region B1 of the first tapering formation 2000, interaction particles and/or interaction radiation is/are detected. For example, secondary electrons and/or backscattered electrons are detected using the first detector 116 and/or the second detector 117 and/or the chamber detector 119 and/or the third detector 121 of the SEM 100. Furthermore, for example, X-ray radiation and/or cathodoluminescence is/are detected with the radiation detector 500. The interaction particles and/or the interaction radiation result(s) from an interaction of the primary electron beam with the first region B1 of the first tapering formation 2000. Furthermore, a first image of the first region B1 of the first tapering formation 2000 is generated using the processor unit 127 based on the detected interaction particles and/or the detected interaction radiation. In method step S3B, the generated first image of the first region B1 of the first tapering formation 2000 is displayed on the monitor 124. This is followed by method steps S4 to S6. Furthermore, in contrast to the embodiment according to FIG. 8, the embodiment according to FIG. 10 has method step S6A, for example after method step S6. In method step S6A, when the primary electron beam is focused onto the second region B2 of the object 125, interaction particles and/or interaction radiation is/are detected. For example, secondary electrons and/or backscattered electrons are detected using the first detector 116 and/or the second detector 117 and/or the chamber detector 119 and/or the third detector 121 of the SEM 100. Furthermore, for example, X-ray radiation and/or cathodoluminescence is/are detected with the radiation detector 500. The interaction particles and/or the interaction radiation result(s) from an interaction of the primary electron beam with the second region B2 of the object 125. Furthermore, a second image of the second region B2 of the object 125 is generated using the processor unit 127 based on the detected interaction particles and/or the detected interaction radiation. In method step S6B, the generated second image of the second region B2 of the object 125 is displayed on the monitor 124. This is followed by method steps S7 to S8. The embodiment according to FIG. 10 ensures that, in addition to the difference or the absolute value of the difference (i.e., in addition to the distance AB between the first region B1 of the first tapering formation 2000 and the second region B2 of the object 125), particle-optical images of the first region B1 of the first tapering formation 2000 and/or of the second region B2 of the object 125 are also presented on the monitor 124.

In a further embodiment of the method according to the invention, provision is additionally or alternatively made for the generated first image of the first region B1 of the first tapering formation 2000 to also be displayed on the monitor 124 when the primary electron beam is focused onto the second region B2 of the object 125 and/or when the generated second image of the second region B2 of the object 125 is displayed on the monitor 124. For example, the first image of the first region B1 and the second image of the second region B2 are at least partially superimposed. In particular, provision is made for the first image of the first region B1 to be used as a background image for the presentation of the second image of the second region B2 when the primary electron beam is focused onto the second region B2 of the object 125. Alternatively, provision is made, for example, for the second image of the second region B2 to be used as a background image for the presentation of the first image of the first region B1 when the primary electron beam is focused onto the first region B1 of the first tapering formation 2000. This embodiment of the method according to the invention ensures that both the generated first image and the generated second image are presented on the monitor 124 even if the primary electron beam is focused only onto one of the regions, that is to say onto the first region B1 of the first tapering formation 2000 or onto the second region B2 of the object 125.

FIG. 11 shows a further embodiment of the method according to the invention. The embodiment according to FIG. 11 is based on the embodiment according to FIG. 8. Reference is made to the explanations given above, which also apply here. In contrast to the embodiment according to FIG. 8, the embodiment according to FIG. 11 has a method step S31, for example after method step S3. In method step S31, the first distance AB1 is output on the monitor 124. This is effected for example by displaying a numerical value and/or by displaying a colour code and/or by displaying a 3D representation representing the first distance AB1 and/or by displaying the first distance AB1 with a pointer and/or by displaying a flashing frequency and/or by displaying a brightness. Additionally or alternatively, the first distance AB1 is acoustically output, for example, by a sound frequency and/or a pitch and/or a pulse frequency and/or a sequence of sounds using a loudspeaker of the monitor 124. Method steps S4 to S6 are performed subsequently. Furthermore, in contrast to the embodiment according to FIG. 8, the embodiment according to FIG. 11 has a method step S61, for example after method step S6. In method step S61, the second distance AB2 is output on the monitor 124. This is effected for example by displaying a numerical value and/or by displaying a colour code and/or by displaying a 3D representation representing the second distance AB2 and/or by displaying the second distance AB2 with a pointer and/or by displaying a flashing frequency and/or by displaying a brightness. Additionally or alternatively, the second distance AB2 is acoustically output, for example, by a sound frequency and/or a pitch and/or a pulse frequency and/or a sequence of sounds using a loudspeaker. Method steps S7 and S8 are performed subsequently.

FIG. 12 shows a further embodiment of the method according to the invention. The embodiment according to FIG. 12 is based on the embodiment according to FIG. 10. Reference is made to the explanations given above, which also apply here. In contrast to the embodiment according to FIG. 10, the embodiment according to FIG. 12 has a method step S31, for example after method step S3. In method step S31, the first distance AB1 is displayed on the monitor 124. This is effected for example by displaying a numerical value and/or by displaying a colour code and/or by displaying a 3D representation representing the first distance AB1 and/or by displaying the first distance AB1 with a pointer and/or by displaying a flashing frequency and/or by displaying a brightness. Additionally or alternatively, the first distance AB1 is acoustically output, for example, by a sound frequency and/or a pitch and/or a pulse frequency and/or a sequence of sounds using a loudspeaker of the monitor 124. Method steps S3A to S6 are performed subsequently. Furthermore, in contrast to the embodiment according to FIG. 10, the embodiment according to FIG. 12 has a method step S61, for example after method step S6. In method step S61, the second distance AB2 is output on the monitor 124. This is effected for example by displaying a numerical value and/or by displaying a colour code and/or by displaying a 3D representation representing the second distance AB2 and/or by displaying the second distance AB2 with a pointer and/or by displaying a flashing frequency and/or by displaying a brightness. Additionally or alternatively, the second distance AB2 is acoustically output, for example, by a sound frequency and/or a pitch and/or a pulse frequency and/or a sequence of sounds using a loudspeaker of the monitor 124. Method steps S6A to S8 are performed subsequently.

In further embodiments of the method according to the invention, provision is additionally or alternatively made for a region which extends both along a first direction with a first length and along a second direction with a second length to be used as the first region B1 of the first tapering formation 2000. Furthermore, a region which extends both along the first direction with the first length and along the second direction with the second length is used as the second region B2 of the object 125. Basically, the first region B1 of the first tapering formation 2000 and the second region B2 of the object 125 have an identical design in a first dimension (first direction) and in a second dimension (second direction). Basically, in this embodiment of the method according to the invention, the first region B1 of the first tapering formation 2000 and the second region B2 of the object 125 differ only by their distance AB from each other (cf. FIG. 9), wherein the distance AB extends along a third dimension (third direction). For example, the first direction, the second direction and the third direction are each arranged perpendicular to each other.

FIG. 13 shows a further embodiment of the method according to the invention. The embodiment according to FIG. 13 is based on the embodiment according to FIG. 8. Reference is made to the explanations given above, which also apply here. In contrast to the embodiment according to FIG. 8, the embodiment according to FIG. 13 has further method steps after method step S8 which are explained below.

In a method step S9, in the embodiment illustrated in FIG. 13, the first unit in the form of the first tapering formation 2000 and/or the second unit in the form of the object 125 is/are moved. Possibilities for moving the first tapering formation 2000 and/or the object 125 have already been discussed in detail further above. Reference is made to these explanations, which also apply here.

In a method step S10 of the embodiment according to FIG. 13, further setting of the control parameter for controlling the first objective lens 107 of the SEM 100 is carried out using the control unit 123 in such a way that the primary electron beam of the SEM 100 is focused onto the first region B1 of the first tapering formation 2000 using the first objective lens 107 (cf. FIG. 9). Alternatively, the primary electron beam of the SEM 100 can be focused onto a further first region B1′ of the first tapering formation 2000, wherein the further first region B1′ of the first tapering formation 2000 can differ from the first region B1 of the first tapering formation 2000. As explained above, the abovementioned control parameter is, for example, a control current or a control voltage. The setting of the control parameter comprises, for example, setting the control parameter in such a way that the first region B1 (or the further first region B1′) of the first tapering formation 2000 is arranged in a further first focal plane of the first objective lens 107. Additionally or alternatively, provision is made for the setting of the control parameter to comprise setting the control parameter to an arbitrary value. Furthermore, the first region B1 (or the further first region B1′) of the tapering formation 2000 is arranged by moving the tapering formation 2000 in a focal plane of the first objective lens 107 determined by the arbitrary value of the control parameter.

In a method step S11 of the embodiment according to FIG. 13, a further first value of the control parameter, for which the primary electron beam is focused onto the first region B1 (or the further first region B1′) of the first tapering formation 2000, is determined using the processor unit 127.

In a method step S12 of the embodiment according to FIG. 13, a further first distance AB1′ (cf. FIG. 9) between the outer boundary of the first objective lens 107 and the first region B1 (or the further first region B1′) of the first tapering formation 2000 is determined using the further first value of the control parameter and the processor unit 127 (cf. FIG. 9). Basically, the further first distance AB1′ is the focal plane distance which is also referred to as the working distance. For example, the further first distance AB1′ is a shortest connection of all possible connections between any point on the outer boundary of the first objective lens 107 and the first region B1 (or the further first region B1′) of the first tapering formation 2000.

In a method step S13 of the embodiment according to FIG. 13, further setting of the control parameter for controlling the first objective lens 107 is carried out using the control unit 123 in such a way that the primary electron beam is focused onto the second region B2 of the object 125 using the first objective lens 107 (cf. FIG. 9). Alternatively, the primary electron beam of the SEM 100 can be focused onto a further second region B2′ of the object 125, wherein the further second region B2′ of the object 125 can differ from the second region B2 of the object 125. The further setting of the control parameter comprises, for example, setting the control parameter in such a way that the second region B2 (or the further second region B2′) of the object 125 is arranged in a further second focal plane of the first objective lens 107. Additionally or alternatively, provision is made for the setting of the control parameter to comprise setting the control parameter to a further arbitrary value. Furthermore, the second region B2 (or the further second region B2′) of the object 125 is arranged by moving the object 125 by means of the object stage 122 in a focal plane of the first objective lens 107 determined by the further arbitrary value.

In a method step S14 of the embodiment according to FIG. 13, a further second value of the control parameter, for which the primary electron beam is focused onto the second region B2 (or the further second region B2′) of the object 125, is determined using the processor unit 127.

In a method step S15 of the embodiment according to FIG. 13, a further second distance AB2′ between the outer boundary of the first objective lens 107 and the second region B2 (or the further second region B2′) of the object 125 is determined using the second value of the control parameter and the processor unit 127 of the SEM 100. Basically, the further second distance AB2′ is also a focal plane distance which is also referred to as the working distance. For example, the further second distance AB2′ is a shortest connection of all possible connections between any point on the outer boundary of the first objective lens 107 and the second region B2 (or the further second region B2′) of the object 125.

In a method step S16 of the embodiment according to FIG. 13, a further difference between the further first distance AB1′ and the further second distance AB2′ is determined using the processor unit 127.

Furthermore, in a method step S17, provision is made for the further difference and/or the absolute value of the further difference to be output on the monitor 124 of the SEM 100. This is effected for example by displaying a numerical value and/or by displaying a colour code and/or by displaying a 3D representation representing the further difference and/or by displaying the further difference and/or the absolute value of the further difference with a pointer and/or by displaying a flashing frequency and/or by displaying a brightness. Additionally or alternatively, the further difference and/or the absolute value of the further difference is/are acoustically output, for example, by a sound frequency and/or a pitch and/or a pulse frequency and/or a sequence of sounds using a loudspeaker of the monitor 124. Basically, the further difference and/or the absolute value of the further difference correspond(s) to the further distance AB′ between the first tapering formation 2000 and the object 125.

FIG. 14 shows yet another embodiment of the method according to the invention. The embodiment of the method according to the invention according to FIG. 14 is based on the embodiment according to FIG. 10. Reference is made to the explanations given above, which also apply here. In contrast to the embodiment according to FIG. 10, the embodiment according to FIG. 14 has method steps S9, S10, S11, S12, S13, S14, S15, S16 and S17 of the embodiment according to FIG. 13. In addition, the embodiment according to FIG. 14 has method step S11A which is carried out, for example, after method step S11. In method step S11A, when the primary electron beam is focused onto the first region B1 (or the further first region B1′) of the first tapering formation 2000, interaction particles and/or interaction radiation is/are detected. For example, secondary electrons and/or backscattered electrons are detected using the first detector 116 and/or the second detector 117 and/or the chamber detector 119 and/or the third detector 121 of the SEM 100. Furthermore, for example, X-ray radiation and/or cathodoluminescence is/are detected with the radiation detector 500. The interaction particles and/or the interaction radiation result(s) from an interaction of the primary electron beam with the first region B1 (or the further first region B1′) of the first tapering formation 2000. Furthermore, a further first image of the first region B1 (or the further first region B1′) of the first tapering formation 2000 is generated using the processor unit 127 based on the detected interaction particles and/or the detected interaction radiation. In a method step S11B, the generated further first image of the first region B1 (or the further first region B1′) of the first tapering formation 2000 is displayed on the monitor 124. This is followed by method steps S12 to S14. Furthermore, the embodiment according to FIG. 14 has method step S14A which is carried out, for example, after method step S14. In method step S14A, when the primary electron beam is focused onto the second region B2 (or the further second region B2′) of the object 125, interaction particles and/or interaction radiation is/are detected. For example, secondary electrons and/or backscattered electrons are detected using the first detector 116 and/or the second detector 117 and/or the chamber detector 119 and/or the third detector 121 of the SEM 100. Furthermore, for example, X-ray radiation and/or cathodoluminescence is/are detected with the radiation detector 500. The interaction particles and/or the interaction radiation result(s) from an interaction of the primary electron beam with the second region B2 (or the further second region B2′) of the object 125. Furthermore, a further second image of the second region B2 (or the further second region B2′) of the object 125 is generated using the processor unit 127 based on the detected interaction particles. In a method step S14B, the generated further second image of the second region B2 (or the further second region B2′) of the object 125 is displayed on the monitor 124. This is followed by method steps S15 to S17.

FIG. 15 shows yet another embodiment of the method according to the invention. The embodiment of the method according to the invention according to FIG. 15 is based on the embodiment according to FIG. 11. Reference is made to the explanations given above, which also apply here. In contrast to the embodiment according to FIG. 11, the embodiment according to FIG. 15 has method steps S9, S10, S11, S12, S13, S14, S15, S16 and S17 of the embodiment according to FIG. 13. In addition, the embodiment according to FIG. 15 has method step S12A which is carried out, for example, after method step S12. In method step S12A, the further first distance AB1′ is output using the monitor 124 of the SEM 100. This is effected for example by displaying a numerical value and/or by displaying a colour code and/or by displaying a 3D representation representing the further first distance AB1′ and/or by displaying the further first distance AB1′ with a pointer and/or by displaying a flashing frequency and/or by displaying a brightness. Additionally or alternatively, the further first distance AB1′ is acoustically output, for example, by a sound frequency and/or a pitch and/or a pulse frequency and/or a sequence of sounds using a loudspeaker. Method steps S13 to S15 follow this. Furthermore, the embodiment according to FIG. 15 has method step S15A which is carried out, for example, after method step S15. In method step S15A, the further second distance AB2′ is output using the monitor 124 of the SEM 100. This is effected for example by displaying a numerical value and/or by displaying a colour code and/or by displaying a 3D representation representing the further second distance AB2′ and/or by displaying the further second distance AB2′ with a pointer and/or by displaying a flashing frequency and/or by displaying a brightness. Additionally or alternatively, the further second distance AB2′ is acoustically output, for example, by a sound frequency and/or a pitch and/or a pulse frequency and/or a sequence of sounds using a loudspeaker. Method steps S16 and S17 follow this.

FIG. 16 shows yet another embodiment of the method according to the invention. The embodiment of the method according to the invention according to FIG. 16 is based on the embodiment according to FIG. 12. Reference is made to the explanations given above, which also apply here. In contrast to the embodiment according to FIG. 12, the embodiment according to FIG. 16 has method steps S9, S10, S11, S12, S13, S14, S15, S16 and S17 of the embodiment according to FIG. 13. In addition, the embodiment according to FIG. 16 has method steps S11A and S11B which are carried out, for example, after method step S11. Method steps S11A and S11B were explained further above with regard to FIG. 14. Reference is made to these explanations, which also apply here. In addition, the embodiment according to FIG. 16 has method steps S14A and S14B which are carried out, for example, after method step S14. Method steps S14A and S14B were explained further above with regard to FIG. 14. Reference is made to these explanations, which also apply here. In addition, the embodiment according to FIG. 16 has method step S12A which is carried out, for example, after method step S12. Method step S12A was explained further above with regard to FIG. 15. Reference is made to these explanations, which also apply here. In addition, the embodiment according to FIG. 16 has method step S15A which is carried out, for example, after method step S15. Method step S15A was explained further above with regard to FIG. 15. Reference is made to these explanations, which also apply here.

All embodiments of the method according to the invention above and below are not restricted to the explained order of the method steps. The invention also encompasses different orders of the method steps that are suitable for achieving the object within the meaning of the invention. Alternatively or additionally, in the method according to the invention, provision is also made to carry out at least two method steps in parallel. Furthermore, the embodiments of the method according to the invention above and below are not restricted to the complete scope of all the method steps mentioned above or further below. In particular, provision is made for individual or a plurality of the abovementioned or following method steps to be omitted in further embodiments.

The features of the invention disclosed in the present description, in the drawings and in the claims may be essential for the realization of the invention in the various embodiments thereof both individually and in any desired combinations. The invention is not restricted to the embodiments described. It may be varied within the scope of the claims and taking into account the knowledge of those skilled in the relevant art.

### LIST OF REFERENCE SIGNS

100 SEM
101 Electron source
102 Extraction electrode
103 Anode
104 Beam guiding tube
105 First condenser lens
106 Second condenser lens
107 First objective lens
108 First aperture unit
108A First aperture
109 Second aperture unit
110 Pole pieces
111 Electric coil
112 Single electrode
113 Tube electrode
114 Holding device
115 Scanning device
116 First detector
116A Opposing field grid
117 Second detector
118 Second aperture
119 Chamber detector
120 Sample chamber
121 Third detector
122 Object stage
123 Control unit
124 Monitor
125 Object
126 Database
127 Processor unit
128 Movement device
200 Combination apparatus
201 Sample chamber
300 Ion beam apparatus
301 Ion beam generator
302 Extraction electrode in the ion beam apparatus
303 Condenser lens
304 Second objective lens
306 Adjustable or selectable aperture unit
307 First electrode arrangement
308 Second electrode arrangement
400 Particle beam apparatus comprising a corrector unit
401 Particle beam column
402 Electron source
403 Extraction electrode
404 Anode
405 First electrostatic lens
406 Second electrostatic lens
407 Third electrostatic lens
408 Magnetic deflection unit
409 First electrostatic beam deflection unit
409A First multi-pole unit
409B Second multi-pole unit
410 Beam deflection device
411A First magnetic sector
411B Second magnetic sector
411C Third magnetic sector
411D Fourth magnetic sector
411E Fifth magnetic sector
411F Sixth magnetic sector
411G Seventh magnetic sector
413A First mirror electrode
413B Second mirror electrode
413C Third mirror electrode
414 Electrostatic mirror
415 Fourth electrostatic lens
416 Second electrostatic beam deflection unit
416A Third multi-pole unit
416B Fourth multi-pole unit
417 Third electrostatic beam deflection unit
418 Fifth electrostatic lens
418A Fifth multi-pole unit
418B Sixth multi-pole unit
419 First analysis detector
420 Beam guiding tube
421 Objective lens
422 Magnetic lens
423 Sixth electrostatic lens
424 Object stage
425 Object
426 Sample chamber
427 Detection beam path
428 Second analysis detector
429 Scanning device
432 Further magnetic deflection element
500 Radiation detector
600 First movement element
601 Housing
602 Second movement element
603 First axis of rotation of the stage
604 Third movement element
605 Fourth movement element
606 Fifth movement element
607 Second axis of rotation of the stage
608 Drive control unit
709 First beam axis
710 Second beam axis
1000 Gas feed device
1000A Manipulator device
1000B Measuring device
1001 Gas feed unit
1001A Manipulator
1001B Tapering formation
1002 First movement unit of the gas feed device
1002A First movement unit of the manipulator device
1002B First movement unit of the tapering formation
1003 Second movement unit of the gas feed device
1003A Second movement unit of the manipulator device
1003B Second movement unit of the tapering formation
1004 Third movement unit of the gas feed device
1004A Third movement unit of the manipulator device
1004B Third movement unit of the tapering formation
2000 First tapering formation
2001 Second tapering formation
2002 Third tapering formation
A Distance
A1 First distance
A2 Second distance
AB Distance
AB′ Further distance
AB1 First distance
AB1′ Further first distance
AB2 Second distance
AB2′ Further second distance
B1 First region
B1′ Further first region
B2 Second region
B2′ Further second region
M1 First drive unit in the form of a motor
M2 Second drive unit in the form of a motor
M3 Third drive unit in the form of a motor
M4 Fourth drive unit in the form of a motor
M5 Fifth drive unit in the form of a motor
OA Optical axis
OA1 First optical axis
OA2 Second optical axis
OA3 Third optical axis
S1 to S17 Method steps
S31 Method step
S61 Method step
S3A, S3B Method steps
S6A, S6B Method steps
S11A, S11B Method steps
S12A Method step
S14A, S14B Method steps
S15A Method step

1. A method for operating a particle beam apparatus, comprising:
setting of a control parameter to control an objective lens of the particle beam apparatus using a control unit of the particle beam apparatus to cause a particle beam from the particle beam apparatus to be focused onto a first region of at least one first unit, which is arranged in a sample chamber of the particle beam apparatus, using the objective lens;
determining, using a processor unit of the particle beam apparatus, a first value of the control parameter, for which the particle beam is focused onto the first region of the at least one first unit;
determining a first distance between an outer boundary of the objective lens and the first region of the at least one first unit using the first value of the control parameter and the processor unit;
setting of the control parameter to control the objective lens using the control unit to cause the particle beam from the particle beam apparatus to be focused onto a second region of at least one second unit, which is arranged in the sample chamber of the particle beam apparatus, using the objective lens;
determining, using the processor unit, a second value of the control parameter, for which the particle beam is focused onto the second region of the at least one second unit;
determining a second distance between the outer boundary of the objective lens and the second region of the at least one second unit using the second value of the control parameter and the processor unit of the particle beam apparatus;
determining a difference between the first distance and the second distance using the processor unit; and
outputting the difference and/or an absolute value of the difference on an output unit of the particle beam apparatus.

2. The method according to claim 1, further comprising:
when the particle beam is focused onto the first region of the at least one first unit, detecting interaction particles and/or interaction radiation using at least one detector of the particle beam apparatus, wherein the interaction particles and/or the interaction radiation result(s) from an interaction of the particle beam with the first region of the at least one first unit, generating a first image of the first region of the at least one first unit using the processor unit based on the detected interaction particles and/or the detected interaction radiation, and displaying the generated first image of the first region of the at least one first unit using the output unit; and
when the particle beam is focused onto the second region of the at least one second unit, detecting interaction particles and/or interaction radiation using the at least one detector of the particle beam apparatus, wherein the interaction particles and/or the interaction radiation result(s) from an interaction of the particle beam with the second region of the at least one second unit, generating a second image of the second region of the at least one second unit using the processor unit based on the detected interaction particles and/or the detected interaction radiation, and displaying the generated second image of the second region of the at least one second unit using the output unit.

3. The method according to claim 2, wherein the generated first image of the first region of the at least one first unit is also displayed using the output unit when the particle beam is focused onto the second region of the at least one second unit and/or when the generated second image of the second region of the at least one second unit is displayed using the output unit.

4. The method according to claim 1, wherein the first distance and/or the second distance are/is output using the output unit.

5. The method according to claim 1, wherein the first region extends both along a first direction with a first length and along a second direction with a second length; and the second region extends both along the first direction with the first length and along the second direction with the second length.

6. The method according to claim 1, further comprising at least one of the following:
the at least one first unit is moved in the sample chamber using a first movement device; and/or
the at least one second unit is moved in the sample chamber using a second movement device.

7. The method according to claim 1, further comprising:
setting the control parameter to control the objective lens of the particle beam apparatus using the control unit to cause the particle beam from the particle beam apparatus to be focused onto a further first region of the at least one first unit using the objective lens;
determining, using the processor unit, a further first value of the control parameter, for which the particle beam is focused onto the further first region of the at least one first unit;
determining a further first distance between the outer boundary of the objective lens and the further first region of the at least one first unit using the further first value of the control parameter and the processor unit;
setting the control parameter to control the objective lens using the control unit to cause the particle beam from the particle beam apparatus to be focused onto a further second region of the at least one second unit using the objective lens;
determining, using the processor unit, a further second value of the control parameter, for which the particle beam is focused onto the further second region of the at least one second unit;
determining a further second distance between the outer boundary of the objective lens and the further second region of the at least one second unit using the further second value of the control parameter and the processor unit of the particle beam apparatus;
determining a further difference between the further first distance and the further second distance using the processor unit; and
outputting the further difference and/or an absolute value of the further difference using the output unit.

8. The method according to claim 7, further comprising:
when the particle beam is focused onto the further first region of the at least one first unit, detecting interaction particles and/or interaction radiation using at least one detector unit of the particle beam apparatus, wherein the interaction particles and/or the interaction radiation result(s) from an interaction of the particle beam with the further first region of the at least one first unit, generating a further first image of the further first region of the at least one first unit using the processor unit based on the detected interaction particles and/or the detected interaction radiation, and displaying the generated further first image of the further first region of the at least one first unit using the output unit; and
when the particle beam is focused onto the further second region of the at least one second unit, detecting interaction particles and/or interaction radiation using the at least one detector unit of the particle beam apparatus, wherein the interaction particles and/or the interaction radiation result(s) from an interaction of the particle beam with the further second region of the at least one second unit, generating a further second image of the further second region of the at least one second unit using the processor unit based on the detected interaction particles and/or the detected interaction radiation, and displaying the generated further second image of the further second region of the at least one second unit using the output unit.

9. The method according to claim 8, wherein the generated further first image of the further first region of the at least one first unit is also displayed using the output unit when the particle beam is focused onto the further second region of the at least one second unit and/or when the generated further second image of the second region of the at least one second unit is displayed using the output unit.

10. The method according to claim 1, wherein an electron beam apparatus and/or an ion beam apparatus is/are used as the particle beam apparatus.

11. The method according to claim 1, wherein the at least one first unit and/or as the at least one second unit are at least one of the following:
a manipulator;
a measuring device;
a measuring device with a tapering formation;
a measuring device that makes electrical contact and/or that makes mechanical contact and/or that dissipates electrical current and/or that supplies electrical current and/or that measures an electrical potential and/or that supplies an electrical potential;
a gas feed device;
a detection unit;
an object to be examined, analyzed and/or processed with the particle beam apparatus.

12. A non-transitory computer readable medium containing software that, when loaded into a processor unit of a particle beam apparatus and executed, controls the particle beam apparatus, the software comprising:
executable code that sets a control parameter to control an objective lens of the particle beam apparatus using a control unit of the particle beam apparatus to cause a particle beam from the particle beam apparatus to be focused onto a first region of at least one first unit, which is arranged in a sample chamber of the particle beam apparatus, using the objective lens;
executable code that determines a first value of the control parameter, for which the particle beam is focused onto the first region of the at least one first unit;
executable code that determines a first distance between an outer boundary of the objective lens and the first region of the at least one first unit using the first value of the control parameter and the processor unit;
executable code that sets the control parameter to control the objective lens using the control unit to cause the particle beam from the particle beam apparatus to be focused onto a second region of at least one second unit, which is arranged in the sample chamber of the particle beam apparatus, using the objective lens;
executable code that determines a second value of the control parameter, for which the particle beam is focused onto the second region of the at least one second unit;
executable code that determines a second distance between the outer boundary of the objective lens and the second region of the at least one second unit using the second value of the control parameter and the processor unit of the particle beam apparatus;
executable code that determines a difference between the first distance and the second distance using the processor unit; and
executable code that outputs the difference and/or an absolute value of the difference on an output unit of the particle beam apparatus.

13. A particle beam apparatus for imaging, processing and/or analyzing an object, comprising:
at least one beam generator that generates at least one particle beam having charged particles;
a sample chamber;
at least one first unit and at least one second unit, wherein the at least one first unit and the at least one second unit are arranged in the sample chamber;
at least one objective lens that focuses the at least one particle beam onto the object, onto the at least one first unit and/or onto the at least one second unit;
a control unit that controls the objective lens;
an output unit; and
a processor unit coupled to a non-transitory computer readable medium containing software that, when executed by the processor unit, causes the particle beam apparatus to perform the following:
setting of a control parameter to control the at least one objective lens using the control unit to cause the at least one particle beam to be focused onto a first region of the at least one first unit using the at least one objective lens;
determining a first value of the control parameter, for which the at least one particle beam is focused onto the first region of the at least one first unit;
determining a first distance between an outer boundary of the at least one objective lens and the first region of the at least one first unit using the first value of the control parameter;
setting of the control parameter to control the at least one objective lens using the control unit to cause the at least one particle beam to be focused onto a second region of the at least one second unit using the at least one objective lens;
determining a second value of the control parameter, for which the at least one particle beam is focused onto the second region of the at least one second unit;
determining a second distance between the outer boundary of the at least one objective lens and the second region of the at least one second unit using the second value of the control parameter;
determining a difference between the first distance and the second distance; and
outputting the difference and/or an absolute value of the difference on the output unit.

14. The particle beam apparatus according to claim 13, wherein the particle beam apparatus has at least one detector that detects interaction particles and/or interaction radiation resulting from an interaction of the at least one particle beam with the object.

15. The particle beam apparatus according to claim 13, wherein the particle beam apparatus further includes at least one of the following:
a first movement device that moves the at least one first unit; and/or
a second movement device that moves the at least one second unit.

16. The particle beam apparatus according to claim 13, wherein the at least one first unit and/or the at least one second unit is/are embodied as at least one of the following:
a manipulator;
a measuring device;
a measuring device with a tapering formation;
a measuring device that makes electrical contact and/or that makes mechanical contact and/or that dissipates electrical current and/or that supplies electrical current and/or that measures an electrical potential and/or that supplies an electrical potential;
a gas feed device;
a detection unit;
an object to be examined, analyzed and/or processed with the particle beam apparatus.

17. The particle beam apparatus according to claim 13, wherein the at least one beam generator is a first beam generator, wherein the at least one particle beam is a first particle beam having first charged particles, wherein the at least one objective lens is a first objective lens that focuses the first particle beam onto the object, onto the at least one first unit and/or onto the at least one second unit, and wherein the particle beam apparatus further comprises:
at least one second beam generator that generates at least one second particle beam having second charged particles; and
at least one second objective lens that focuses the at least one second particle beam onto the object, onto the at least one first unit and/or onto the at least one second unit.

18. The particle beam apparatus according to claim 13, wherein the particle beam apparatus is an electron beam apparatus and/or an ion beam apparatus.
